(19) United States
(12) Patent Application Publication
(10) Pub. No.: US 2009/0238227 A1
(43) Pub. Date: Sep. 24, 2009

(54) Semiconductor light emitting device

(75) Inventors: Masashi Kubota, Kyoto (JP); Kuniyoshi Okamoto, Kyoto (JP); Taketoshi Tanaka, Kyoto (JP); Yoshinori Tanaka, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/379,946

(22) Filed: Mar. 4, 2009

(30) Foreign Application Priority Data
Mar. 5, 2008 (JP) 2008-054705
Mar. 27, 2008 (JP) 2008-084219
Mar. 27, 2008 (JP) 2008-084220

(51) Int. Cl. H01S 5/00

(52) U.S. Cl. 372/45.011

(57) ABSTRACT

A semiconductor light emitting device is made of a group III nitride semiconductor having a major growth surface defined by a nonpolar plane or a semipolar plane, and has a quantum well layer containing In in a light emitting layer. A strain compensation layer made of a group III nitride semiconductor containing Al and having a lattice constant smaller than the lattice constant of the quantum well layer in a strain-free state is interposed in the light emitting layer of a quantum well structure having the quantum well layer and a barrier layer or in an adjacent layer adjacent to the light emitting layer.

### BACKGROUND OF THE INVENTION

1. Field of the Invention

The present invention relates to a semiconductor light emitting device (a light emitting diode, a laser diode or the like) employing group III nitride semiconductors.

2. Description of Related Art

Group III-V semiconductors employing nitrogen as a group V element are referred to as group III nitride semiconductors, and typical examples thereof include aluminum nitride (AlN), gallium nitride (GaN) and indium nitride (InN), which can be generally expressed as Al_{X}In_{Y}Ga_{1-X-Y}N (0≦x≦1, 0≦y≦1 and 0≦X+Y≦1).

A short wavelength laser source emitting a blue or green laser beam is increasingly employed in the fields of high-density recording in an optical disk represented by a DVD, image processing, medical instruments, measuring instruments and the like. Such a short wavelength laser source includes a laser diode employing GaN semiconductors, for example.

A GaN semiconductor laser diode is manufactured by growing group III nitride semiconductors on a gallium nitride (GaN) substrate having a major surface defined by a c-plane by metal-organic vapor phase epitaxy (MOVPE). More specifically, an n-type GaN contact layer, an n-type AlGaN cladding layer, an n-type GaN guide layer, a light emitting layer (active layer), a p-type GaN guide layer, a p-type AlGaN cladding layer and a p-type GaN contact layer are successively grown on the GaN substrate by metal-organic vapor phase epitaxy, to form a semiconductor multilayer structure consisting of the semiconductor layers. The light emitting layer emits light by recombination of electrons and positive holes injected from the n-type layers and the p-type layers respectively. The light is confined between the n-type AlGaN cladding layer and the p-type AlGaN cladding layer, and is propagated in a direction orthogonal to the stacking direction of the semiconductor multilayer structure. Cavity end faces are formed on both ends in the propagation direction, so that the light is resonated and amplified while repeating induced emission between the pair of cavity end faces and partially emitted from the cavity end faces as laser beams.

### SUMMARY OF THE INVENTION

One of important characteristics of a semiconductor laser diode is a threshold current (oscillation threshold) for causing laser oscillation. Energy efficiency of the laser oscillation is improved as the threshold current is reduced.

However, light emitted from a light emitting layer grown with a major surface defined by a c-plane is randomly polarized, and hence the ratio of light contributing to oscillation of a TE mode is small. Therefore, efficiency of laser oscillation is not necessarily excellent, and hence the semiconductor laser diode should be improved in order to reduce the threshold current.

Therefore, a laser diode having a major surface defined by a nonpolar plane such as an m-plane is proposed. When a laser diode is manufactured in a group III nitride semiconductor multilayer structure having major crystal growth surfaces defined by m-planes, for example, a light emitting layer emits light containing a large quantity of a polarization component parallel to the m-planes (more specifically, a polarization component in an a-axis direction). Thus, a large ratio of the light emitted in the light emitting layer can contribute to laser oscillation, whereby efficiency of the laser oscillation is improved and the threshold current can be reduced.

When the light emitting layer has a quantum well structure (more specifically, a quantum well structure containing In), separation of carriers resulting from spontaneous piezoelectric polarization in a quantum well is suppressed, and hence the luminous efficiency is increased. When major surfaces of crystal growth are defined by m-planes, crystals can be extremely stably grown and crystallinity can be improved as compared with a case of defining the major surfaces of crystal growth by c-planes or other crystal planes. Consequently, a high-performance laser diode can be manufactured.

In order to elongate an emission wavelength to not less than 450 nm, on the other hand, the In composition in a quantum well layer must be increased. In order to ensure difference between refractive indices of a cladding layer and a guide layer, an InGaN layer must be applied to the guide layer.

If an InGaN quantum well layer and an InGaN guide layer are coherently grown on an m-plane GaN layer, however, in-plane anisotropic compressive stress acts on the layers. More specifically, relatively large compressive stress is developed in a direction perpendicular to a c-axis, i.e., along an a-axis direction. This is because the a-axis lattice constant of InGaN is greater than that of GaN. If the In composition in or the thickness of the InGaN quantum well layer or the InGaN guide layer is increased, therefore, crystal defects are formed along an a-axis. The crystal defects are observed with a fluorescent microscope as dark lines parallel to the a-axis. Therefore, the defects are conceivably nonluminous. If such nonluminous defects can be suppressed, the luminous efficiency can conceivably be further improved.

The problem is not specific to the laser diode, but a similar problem arises also in a case of manufacturing another light emitting device such as a light emitting diode with group III nitride semiconductors having major surfaces defined by m-planes. Such a problem arises also in a light emitting device employing group III nitride semiconductors having major growth surfaces defined by other nonpolar planes such as a-planes or semipolar planes.

Accordingly, an object of the present invention is to provide a semiconductor light emitting device improved in luminous efficiency with group III nitride semiconductors having major growth surfaces defined by nonpolar planes or semipolar planes.

The foregoing and other objects, features and effects of the present invention will become more apparent from the following detailed description of the embodiments with reference to the attached drawings.

### BRIEF DESCRIPTION OF THE DRAWINGS

FIG. 1 is a perspective view for illustrating the structure of a semiconductor laser diode according to a first embodiment of the present invention.

FIG. 2 is a longitudinal sectional view taken along a line II-II in FIG. 1.

FIG. 3 is a cross sectional view taken along a line III-III in FIG. 1.

FIG. 4 is a schematic sectional view for illustrating the structure of a light emitting layer of the semiconductor laser diode.

FIG. 5 is a schematic diagram for illustrating the structures of insulating films (reflecting films) formed on cavity end faces.

FIG. 6 is a schematic diagram showing a unit cell of the crystal structure of a group III nitride semiconductor.

FIG. 7 is a graph showing InN molar fraction dependency of in-plane compressive strain in an InGaN layer coherently grown on an m-plane GaN substrate.

FIG. 8 is a graph showing AlN molar fraction dependency of in-plane compressive strain in an AlGaN layer coherently grown on the m-plane GaN substrate.

FIG. 9 is a schematic diagram for illustrating the structure of a treating apparatus for growing layers constituting a group III nitride semiconductor multilayer structure.

FIGS. 10A and 10B are diagrams showing results of simulation in a case of setting the thickness of a barrier layer to 3 nm.

FIGS. 11A and 11B are diagrams showing results of simulation in a case of setting the thickness of the barrier layer to 5 nm.

FIGS. 12A and 12B are diagrams showing results of simulation in a case of setting the thickness of the barrier layer to 8 nm.

FIGS. 13A and 13B are diagrams showing results of simulation in a case of setting the thickness of the barrier layer to 9 nm.

FIG. 14 is a schematic sectional view showing the structure of a light emitting layer of a semiconductor laser diode according to a second embodiment of the present invention.

FIG. 15 is a schematic sectional view showing the structure of a light emitting layer of a semiconductor laser diode according to a third embodiment of the present invention.

FIG. 16 is a schematic sectional view showing the structure of a light emitting layer of a semiconductor laser diode according to a fourth embodiment of the present invention.

FIG. 17 is a schematic sectional view for illustrating the structure of a light emitting diode according to a fifth embodiment of the present invention.

FIG. 18 is a perspective view showing the structure of a semiconductor laser diode according to a sixth embodiment of the present invention.

FIG. 19 is a longitudinal sectional view taken along a line VIII-VIII in FIG. 18.

FIG. 20 is a graph showing forward voltages (Vf) of semiconductor laser diodes prepared according to Examples and comparative examples with an injection current of 50 mA.

FIG. 21 is a graph showing an I-V curve of a semiconductor laser diode prepared according to Example 1.

FIG. 22 is a graph showing an I-V curve of a semiconductor laser diode prepared according to Example 2.

FIG. 23 is a graph showing an I-V curve of a semiconductor laser diode prepared according to Example 3.

FIG. 24 is a graph showing the relation between annealing temperatures and forward voltages (Vf) in a case of bonding Pd/Au electrodes to p-type GaN layers having major growth surfaces defined by a c-plane and an m-plane respectively and annealing the same.

### DETAILED DESCRIPTION OF PREFERRED EMBODIMENTS

A semiconductor light emitting device according to an embodiment of the present invention is made of a group III nitride semiconductor having a major growth surface defined by a nonpolar plane or a semipolar plane, and has a quantum well layer containing In in a light emitting layer. In the semiconductor light emitting device, a strain compensation layer made of a group III nitride semiconductor containing Al and having a lattice constant smaller than the lattice constant of the quantum well layer in a strain-free state is interposed in the light emitting layer of a quantum well structure having the quantum well layer and a barrier layer or in an adjacent layer adjacent to the light emitting layer.

The quantum well layer is made of a group III nitride semiconductor containing In (an InGaN layer, for example), and hence has a relatively large lattice constant in a strain-free state. When the quantum well layer is coherently grown on an underlayer (a GaN layer, for example), therefore, compressive strain is caused in a direction along the major growth surface (defined by a nonpolar plane or a semipolar plane). On the other hand, the strain compensation layer is made of the group III nitride semiconductor containing Al, and hence has a relatively small lattice constant in the strain-free state. When the strain compensation layer is coherently grown on an underlayer, therefore, tensile strain is caused in a direction along the major growth surface (defined by a nonpolar plane or a semipolar plane). Such a strain compensation layer is so provided in the light emitting layer or in the adjacent layer adjacent to the light emitting layer that compressive stress in the quantum well layer can be relaxed. Consequently, the number of crystal defects in the quantum well layer can be reduced, whereby luminous efficiency can be improved.

The strain compensation layer may be formed by an AlGaN layer, for example. A small quantity of In (In remaining in the atmosphere of a crystal growth chamber, for example) may be incorporated into the AlGaN layer.

When provided in the adjacent layer, the strain compensation layer is preferably provided in an adjacent layer formed in advance of the light emitting layer. Thus, compressive stress in the quantum well layer provided in the light emitting layer can be effectively relaxed. When the group III nitride semiconductor is grown on a substrate, for example, the strain compensation layer is preferably provided in an adjacent layer disposed between the light emitting layer and the substrate.

The strain compensation layer may be provided in the barrier layer. According to the structure, the strain compensation layer is disposed adjacently to the quantum well layer. Thus, compressive stress in the quantum well layer can be efficiently reduced.

The barrier layer may be entirely or partially formed by the strain compensation layer. More specifically, the overall barrier layer may be formed by an AlGaN layer, or the barrier layer may be constituted of an InGaN layer (having an In composition smaller than that in the quantum well layer) and an AlGaN layer (the strain compensation layer). When the strain compensation layer is constituted of the InGaN layer and the AlGaN layer, the AlGaN strain compensation layer is preferably interposed between the InGaN layer and the quantum well layer.

The strain compensation layer may be provided to be in contact with the quantum well layer. According to the structure, the strain compensation layer is in contact with the quantum well layer, whereby compressive stress in the quantum well layer can be more effectively reduced.

When provided in the adjacent layer, the strain compensation layer is preferably in contact with the quantum well structure. According to the structure, the strain compensation layer provided in the adjacent layer is in contact with the quantum well structure, whereby compressive stress in the quantum well layer can be effectively reduced, and crystal defects can be suppressed as a result. More specifically, the strain compensation layer is preferably in contact with the barrier layer of the quantum well structure.

Alternatively, the strain compensation layer may be provided in the adjacent layer, and not in contact with the quantum well structure. Also according to the structure, compressive stress in the quantum well layer can be effectively reduced, and the number of crystal defects in the quantum well layer can be reduced.

The adjacent layer may be made of a group III nitride semiconductor (InGaN, for example) containing In. In the case of such a structure, compressive stress is caused also in the adjacent layer, and hence the number of crystal defects may be increased due to compressive stress in the quantum well layer. In this case, the number of crystal defects in the quantum well layer can be effectively reduced by providing the strain compensation layer in the light emitting layer or in the adjacent layer.

The adjacent layer may include a guide layer and a cladding layer, and the cladding layer may be made of a group III nitride semiconductor having an average Al composition of not more than 5%. When an emission wavelength of the light emitting layer is set in a long-wave range of not less than 450 nm, for example, an InGaN layer and an AlGaN layer may be applied to the guide layer and the cladding layer respectively. An excellent light confining structure can be formed by setting the average Al composition in the cladding layer to not more than 5%.

Preferably, the quantum well structure includes at least one quantum well layer having a thickness of not more than 100 Å. When the thickness of the quantum well layer is set to not more than 100 Å, luminous efficiency can be improved due to a quantum effect. The number of crystal defects resulting from compressive stress in such a thin quantum well layer is reduced due to the strain compensation layer. Therefore, excellent luminous efficiency can be implemented synergistically with the quantum effect.

Preferably, the major growth surface is defined by an m-plane. A group III nitride semiconductor crystal having a major surface defined by an m-plane is stably grown, and has excellent crystallinity. Compressive stress in the quantum well layer can be effectively reduced by introducing the strain compensation layer into the semiconductor light emitting device constituted of such a group III nitride semiconductor having excellent crystallinity, whereby the quantum well layer has an extremely small number of crystal defects. Thus, excellent luminous efficiency can be implemented.

Embodiments the present invention are now described in more detail with reference to the attached drawings.

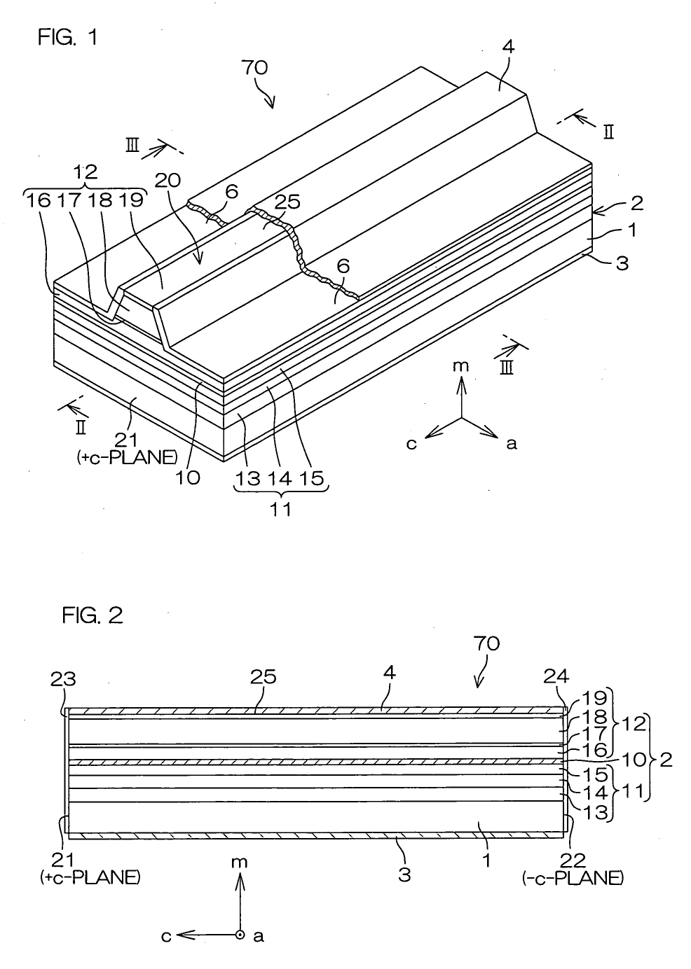

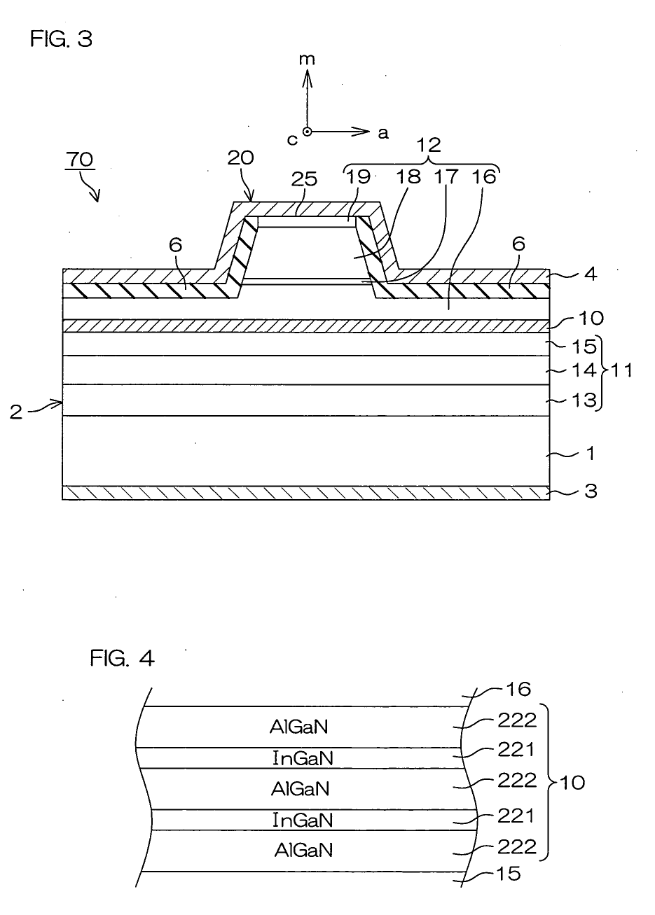

FIG. 1 is a perspective view for illustrating the structure of a semiconductor laser diode according to an embodiment of the present invention, FIG. 2 is a longitudinal sectional view taken along a line II-II in FIG. 1, and FIG. 3 is a cross sectional view taken-along a line III-III in FIG. 1.

A semiconductor laser diode 70 is a Fabry-Perot laser diode including a substrate 1, a group III nitride semiconductor multilayer structure 2 formed on the substrate 1 by crystal growth, an n-type electrode 3 formed to be in contact with the rear surface (the surface opposite to the group III nitride semiconductor multilayer structure 2) of the substrate 1 and a p-type electrode 4 formed to be in contact with the surface (a major growth surface) of the group III nitride semiconductor multilayer structure 2.

The substrate 1 is constituted of a GaN monocrystalline substrate in the embodiment. The major surface of the substrate 1 is defined by an m-plane which is one of nonpolar planes (an a-plane and an m-plane), and the group III nitride semiconductor multilayer structure 2 is formed by crystal growth on the major surface. Therefore, the group III nitride semiconductor multilayer structure 2 is made of group III nitride semiconductors having major crystal growth surfaces defined by m-planes.

Layers forming the group III nitride semiconductor multilayer structure 2 are coherently grown with respect to the substrate 1. Coherent growth denotes crystal growth in a state keeping continuity of lattice from an underlayer. Lattice mismatching with the underlayer is absorbed by strain of the lattice of the crystal-grown layer, to keep continuity of the lattice on the interface between the layer and the underlayer. The value of a-axis lattice constant of InGaN in a strain-free state is greater than that of GaN, and hence compressive stress (compressive strain) in an a-axis direction is caused in an InGaN layer. On the other hand, an a-axis lattice constant of AlGaN in a strain-free state is smaller than that of GaN, and hence tensile stress (tensile strain) in the a-axis direction is caused in an AlGaN layer.

The group III nitride semiconductor multilayer structure 2 includes a light emitting layer (active layer) 10, an n-type semiconductor layered portion 11 and a p-type semiconductor layered portion 12. The n-type semiconductor layered portion 11 is disposed on a side of the light emitting layer 10 closer to the substrate 1, and the p-type semiconductor layered portion 12 is disposed on a side of the light emitting layer 10 closer to the p-type electrode 4. Thus, the light emitting layer 10 is held between the n-type semiconductor layered portion 11 and the p-type semiconductor layered portion 12, and a double heterojunction is provided. Electrons and positive holes are injected into the light emitting layer 10 from the n-type semiconductor layered portion 11 and the p-type semiconductor layered portion 12 respectively. The electrons and the positive holes are recombined in the light emitting layer 10, to emit light.

The n-type semiconductor layered portion 11 is formed by successively stacking an n-type GaN contact layer 13 (having a thickness of 2 μm, for example), an n-type AlGaN cladding layer 14 (having a thickness of not more than 1.5 μm such as a thickness of 1.0 μm, for example) and an n-type InGaN guide layer 15 (having a thickness of 0.1 μm, for example) from the side closer to the substrate 1. On the other hand, the p-type semiconductor layered portion 12 is formed by successively stacking a p-type InGaN guide layer 16 (having a thickness of 0.1 μm, for example), a p-type AlGaN electron blocking layer 17 (having a thickness of 20 nm, for example), a p-type AlGaN cladding layer 18 (having a thickness of not more than 1.5 μm such as a thickness of 0.4 μm, for example) and a p-type GaN contact layer 19 (having a thickness of 0.3 μm, for example) on the light emitting layer 10.

The n-type GaN contact layer 13 and the p-type GaN contact layer 19 are low-resistance layers for attaining ohmic contact with the n-type electrode 3 and the p-type electrode 4 respectively. The n-type GaN contact layer 13 is made of an n-type semiconductor prepared by doping GaN with Si, for example, serving as an n-type dopant in a high concentration (3×10¹⁸ cm⁻³, for example). The p-type GaN contact layer 19 is formed by a p-type semiconductor layer prepared by doping GaN with Mg serving as a p-type dopant in a high concentration (3×10¹⁹ cm⁻³, for example).

The n-type AlGaN cladding layer 14 and the p-type AlGaN cladding layer 18 provide a light confining effect confining the light from the light emitting layer 10 therebetween. The n-type AlGaN cladding layer 14 is made of an n-type semiconductor prepared by doping AlGaN with Si, for example, serving as an n-type dopant (in a doping concentration of 1×10¹⁸ cm⁻³, for example). The p-type AlGaN cladding layer 18 is formed by a p-type semiconductor layer prepared by doping AlGaN with Mg serving as a p-type dopant (in a doping concentration of 1×10¹⁹ cm⁻³, for example). The band gap of the n-type AlGaN cladding layer 14 is wider than that of the n-type InGaN guide layer 15, and the band gap of the p-type AlGaN cladding layer 18 is wider than that of the p-type InGaN guide layer 16. Thus, the light can be excellently confined, and a semiconductor laser diode having a low threshold and high efficiency can be implemented.

When an emission wavelength of the light emitting layer 10 is set in a long-wave range of not less than 450 nm, each of the n-type AlGaN cladding layer 14 and the p-type AlGaN cladding layer 18 is preferably constituted of AlGaN having an average Al composition of not more than 5%. Thus, excellent light confinement can be implemented. Each of the cladding layers 14 and 18 can also be constituted of a superlattice structure of an AlGaN layer and a GaN layer. Also in this case, the average Al compositions in the overall cladding layers 14 and 18 are preferably set to not more than 5%.

The n-type InGaN guide layer 15 and the p-type InGaN guide layer 16 are semiconductor layers providing a carrier confining effect for confining carriers (the electrons and the positive holes) in the light emitting layer 10, and form a light confining structure in the light emitting layer 10 along with the cladding layers 14 and 18. Thus, the efficiency of recombination of the electrons and the positive holes in the light emitting layer 10 is improved. The n-type InGaN guide layer 15 is made of an n-type semiconductor prepared by doping InGaN with Si, for example, serving as an n-type dopant (in a doping concentration of 1×10¹⁸ cm⁻³, for example), while the p-type InGaN guide layer 16 is made of a p-type semiconductor prepared by doping InGaN with Mg, for example, serving as a p-type dopant (in a doping concentration of 5×10¹⁸ cm⁻³, for example).

The p-type AlGaN electron blocking layer 17 is made of a p-type semiconductor prepared by doping AlGaN with Mg, for example, serving as a p-type dopant (in a doping concentration of 5×10¹⁸ cm⁻³, for example), and improves the efficiency of recombination of the electrons and the positive holes by preventing the electrons from flowing out of the light emitting layer 10.

The light emitting layer 10, having an MQW (multiple-quantum well) structure containing InGaN, for example, is a layer for emitting light by recombination of the electrons and the positive holes and amplifying the emitted light.

According to the embodiment, the light emitting layer 10 has the multiple-quantum well (MQW) structure formed by alternately repetitively stacking quantum well layers made of InGaN (each having a thickness of 3 nm, for example) 221 and barrier layers made of AlGaN (each having a thickness of 9 nm, for example) 222 by a plurality of cycles, as shown in FIG. 4. In this case, the composition ratio of In in each quantum well layer 221 made of InGaN is set to not less than 5% so that the band gap thereof is relatively reduced, while the band gap of each barrier layer 222 made of AlGaN is relatively increased. The quantum well layers 221 and the barrier layers 222 are alternately repetitively stacked by two to seven cycles, for example, to constitute the light emitting layer 10 having the multiple-quantum well structure. The emission wavelength corresponds to the band gap of the quantum well layers 221, and the band gap can be adjusted by adjusting the composition ratio of indium (In). The band gap is reduced and the emission wavelength is increased as the composition ratio of indium is increased. According to the embodiment, the emission wavelength is set to 400 nm to 550 nm, more preferably to 450 nm to 550 nm, by adjusting the composition of In in each quantum well layer (InGaN layer) 221. In the multiple-quantum well structure, the number of the quantum well layers 221 containing In is preferably set to not more than 3.

The thickness of each barrier layer 222 is set to 3 nm to 8 nm (7 nm, for example). Thus, an average refractive index around the light emitting layer 10 can be increased, whereby an excellent light confining effect is attained, and a low threshold current can be implemented. For example, a threshold current of not more than 100 mA forming the standard of continuous wave oscillation can be implemented. The function of the barrier layer 222 is hard to obtain if the thickness thereof is less than 3 nm, while the light confining effect around the light emitting layer 10 may be weakened to cause difficulty in continuous wave oscillation if the thickness of the barrier layer 222 exceeds 8 nm.

In order to further increase the average refractive index around the light emitting lay 10 and more strongly confine the light, the Al composition in each barrier layer 222 is preferably set to not more than 5%.

As shown in FIG. 1 etc., the p-type semiconductor layered portion 12 is partially removed, to form a ridge stripe 20. More specifically, the p-type contact layer 19, the p-type AlGaN cladding layer 18, the p-type AlGaN electron blocking layer 17 and the p-type InGaN guide layer 16 are partially removed by etching, to form the ridge stripe 20 having a generally trapezoidal (mesa) shape in cross sectional view. The ridge stripe 20 is formed along a c-axis direction.

The group III nitride semiconductor multilayer structure 2 has a pair of end faces 21 and 22 (cleavage planes) formed by cleaving both ends of the ridge stripe 20 in the longitudinal direction. The pair of end faces 21 and 22 are parallel to each other, and both are perpendicular to c-axes. Thus, a Fabry-Perot cavity having the end faces 21 and 22 as cavity end faces is formed by the n-type InGaN guide layer 15, the light emitting layer 10 and the p-type InGaN guide layer 16. In other words, the light emitted in light emitting layer 10 reciprocates between the cavity end faces 21 and 22, and is amplified by induced emission. The amplified light is partially extracted from the cavity end faces 21 and 22 as laser beams outward from the device.

The n-type electrode 3 and the p-type electrode 4, made of Al metal, for example, are ohmic-connected to the p-type contact layer 19 and the substrate 1 respectively. An insulating layer 6 covering the exposed surfaces of the p-type InGaN guide layer 16, the p-type AlGaN electron blocking layer 17 and the p-type AlGaN cladding layer 18 is provided so that the p-type electrode 4 is in contact with only the p-type GaN contact layer 19 on the top face (a striped contact region) of the ridge stripe 20. Thus, a current can be concentrated on the ridge stripe 20, whereby efficient laser oscillation is enabled. On the surface of the ridge stripe 20, a region excluding the contact region with the p-type electrode 4 is covered and protected with the insulating layer 6, whereby lateral light confinement can be moderated and control can be simplified, while leakage currents from side surfaces can be prevented. The insulating layer 6 can be made of an insulating material such as SiO₂ or ZrO₂, for example, having a refractive index greater than 1.

The top face of the ridge stripe 20 is defined by an m-plane, and the p-type electrode 4 is formed on the m-plane. The rear surface of the substrate 1 provided with the n-type electrode 3 is also defined by an m-plane. Thus, both of the p-type electrode 4 and the n-type electrode 3 are formed on m-planes, whereby reliability capable of sufficiently withstanding a high laser output and a high-temperature operation can be implemented.

The p-type electrode 4 may be made of metal containing Pt. More specifically, the p-type electrode 4 can be constituted of metal having a two-layer structure formed by a lower layer (work function: 5.3 eV, thickness: 5 to 50 nm) mainly containing Pt and in contact with the p-type GaN contact layer 19 and an upper layer (thickness: 10 to 150 nm) mainly containing Au and stacked on the lower layer, for example. In this case, the p-type electrode 4 is formed on the insulating layer 6 and a major growth surface 25 (defined by an m-plane) of the p-type GaN contact layer 19 so that the lower layer mainly containing Pt is in contact with the major growth surface 25 of the p-type GaN contact layer 19 exposed from the insulating layer 6 as the top face of the ridge stripe 20. In other words, the p-type electrode 4 is so formed that the layer containing Pt is in contact with the major growth surface 25 defined by an m-plane. Thus, Pt (work function: 5.3 eV) can be brought into contact with the major growth surface 25, defined by an m-plane, of the GaN contact layer 19, whereby excellent ohmic contact can be attained with respect to the p-type GaN contact layer 19. Consequently, reduction in electrical characteristics of the semiconductor laser diode 70 can be suppressed, whereby laser characteristics can be improved.

The cavity end faces 21 and 22 are covered with insulating films 23 and 24 (not shown in FIG. 1) respectively. The cavity end face 21 is a +c-axis-side end face, and the cavity end face 22 is a −c-axis-side end face. In other words, the crystal plane of the cavity end face 21 is a +c-plane, and the crystal plane of the cavity end face 22 is a −c-plane. The insulating film 24 on the −c-plane-side can function as a protective film protecting the chemically weak −c-plane dissolved in alkali, and contributes to improvement in the reliability of the semiconductor laser diode 70.

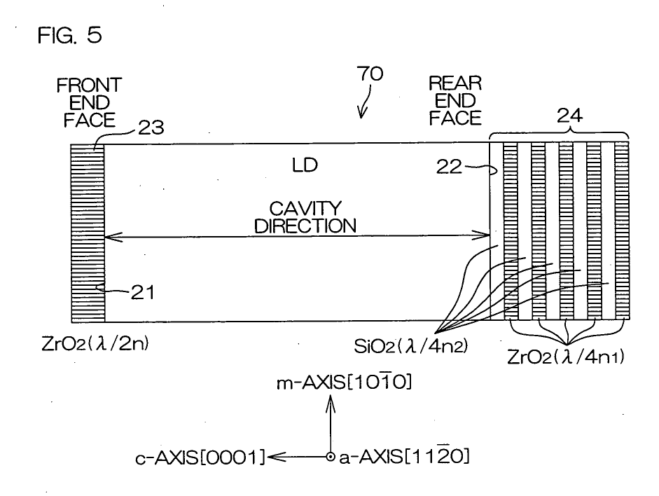

As schematically shown in FIG. 5, the insulating film 23 formed to cover the cavity end face 21 defined by the +c-plane consists of a single film of ZrO₂, for example. On the other hand, the insulating film 24 formed on the cavity end face 22 defined by the −c-plane is constituted of a multiple reflection film formed by alternately repetitively stacking SiO₂ films and ZrO₂ films a plurality of times (five times in the example of FIG. 5), for example. The thickness of the single film of ZrO₂ constituting the insulating film 23 is set to λ/2n₁ (where λ represents the emission wavelength of the light emitting layer 10, and n₁ represents the refractive index of ZrO₂). On the other hand, the multiple reflection film constituting the insulating film 24 has a structure obtained by alternately stacking SiO₂ films each having a thickness λ/4n₂ (where n₂ represents the refractive index of SiO₂) and ZrO₂ films each having a thickness λ/4n₁. Also as to the cavity end face 21 defined by the +c-plane, a multilayer film formed by layers made of materials (ZrO₂ and SiO₂, for example) having different refractive indices and having the aforementioned thicknesses may be employed as a protective film in response to necessary reflectance.

According to such a structure, the reflectance on the +c-axis-side end face 21 is small, and that on the −c-axis-side end face 22 is large. More specifically, the reflectance on the +c-axis-side end face 21 is set to about 20%, and the reflectance on the −c-axis-side end face 22 is about 99.5% (generally 100%), for example. Therefore, a larger laser output is emitted from the +c-axis-side end face 21. In other words, the +c-axis-side end face 21 serves as a laser emitting end face in the semiconductor laser diode 70.

According to such a structure, light having a wavelength of 450 nm to 550 nm can be emitted by connecting the n-type electrode 3 and the p-type electrode 4 to a power source and injecting the electrons and the positive holes into the light emitting layer 10 from the n-type semiconductor layered portion 11 and the p-type semiconductor layered portion 12 respectively thereby recombining the electrons and the positive holes in the light emitting layer 10. The light reciprocates between the cavity end faces 21 and 22 along the guide layers 15 and 16, and is amplified by induced emission. Then, a larger quantity of laser output is extracted from the cavity end face 21 serving as the laser emitting end face.

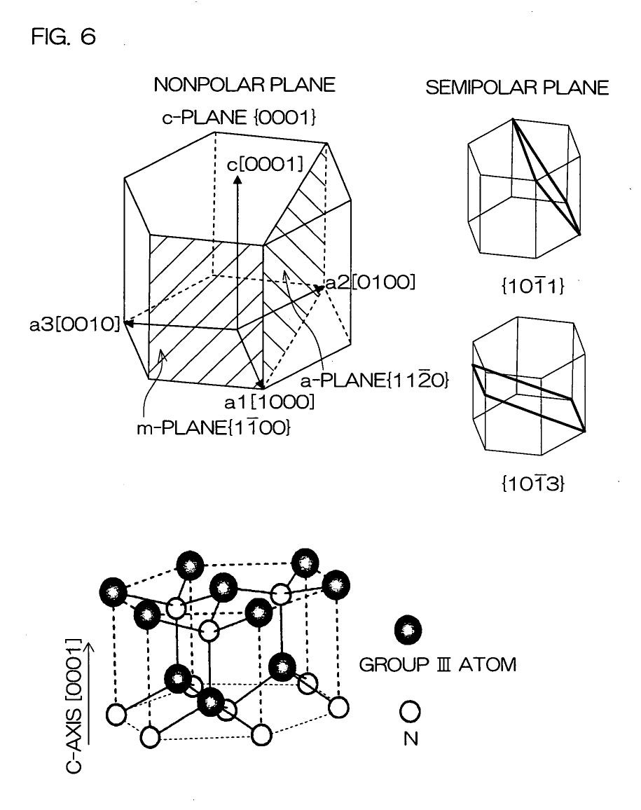

FIG. 6 is a schematic diagram showing a unit cell of the crystal structure of a group III nitride semiconductor. The crystal structure of the group III nitride semiconductor can be approximated by a hexagonal system, and four nitrogen atoms are bonded to each group III atom. The four nitrogen atoms are located on four vertices of a regular tetrahedron having the group III atom disposed at the center thereof. One of the four nitrogen atoms is located in a +c-axis direction of the group III atom, while the remaining three nitrogen atoms are located on a −c-axis side of the group III atom. Due to the structure, the direction of polarization is along the c-axis in the group III nitride semiconductor.

The c-axis is along the axial direction of a hexagonal prism, and a surface (the top face of the hexagonal prism) having the c-axis as a normal is a c-plane (0001). When a crystal of the group III nitride semiconductor is cleaved along two planes parallel to the c-plane, group III atoms align on the crystal plane (+c-plane) on the +c-axis side, and nitrogen atoms align on the crystal plane (−c-plane) on the −c-axis side. Therefore, c-planes, exhibiting different properties on the +c-axis side and the −c-axis side, are called polar planes.

The +c-plane and the −c-plane are different crystal planes, and hence responsively exhibit different physical properties. More specifically, it has been recognized that the +c-plane has high durability against chemical reactivity such as high resistance against alkali, while the −c-plane is chemically weak and dissolved in alkali, for example.

On the other hand, the side surfaces of the hexagonal prism are defined by m-planes (10-10) respectively, and a surface passing through a pair of unadjacent ridges is defined by an a-plane (11-20). The crystal planes, perpendicular to the c-planes and orthogonal to the direction of polarization, are planes having no polarity, i.e., nonpolar planes. Further, crystal planes inclined (neither parallel nor perpendicular) with respect to the c-planes, obliquely intersecting with the direction of polarization, are planes having slight polarity, i.e., semipolar planes. Specific examples of the semipolar planes are planes such as a (10-1) plane, a (10-1-3) plane, a (11-22) plane and the like.

T. Takeuchi et al., Jap. J. Appl. Phys. 39, 413-416, 2000 describes the relation between angles of deviation of crystal planes with respect to c-planes and polarization of the crystal planes in normal directions. From the document, it can be said that a (11-24) plane, a (10-12) plane etc. are also less polarized planes, and powerful crystal planes employable for extracting light of a large polarization state.

For example, a GaN monocrystalline substrate having a major surface defined by an m-plane can be cut out of a GaN monocrystal having a major surface defined by a c-plane. The m-plane of the cut substrate is polished by chemical mechanical polishing, for example, so that azimuth errors with respect to both of a (0001) direction and a (11-20) direction are within ±1° (preferably within ±0.3°). Thus, a GaN monocrystalline substrate having a major surface defined by an m-plane with no crystal defects such as dislocations and stacking faults is obtained. Only steps of an atomic level are formed on the surface of such a GaN monocrystalline substrate.

The group III nitride semiconductor multilayer structure 2 constituting a semiconductor laser diode structure is grown on the GaN monocrystalline substrate obtained in such a manner by metal-organic vapor phase epitaxy.

When the group III nitride semiconductor multilayer structure 2 having the major growth surface defined by an m-plane is grown on the GaN monocrystalline substrate 1 having the major surface defined by an m-plane and a section along an a-plane is observed with an electron microscope (STEM: scanning transmission electron microscope), no striations showing the presence of dislocations are observed in the group III nitride semiconductor multilayer structure 2. When the surface state is observed with an optical microscope, it is understood that planarity in a c-axis direction (the difference between the heights of a terminal portion and a lowermost portion) is not more than 10 Å. This means that planarity of the light emitting layer 10, particularly the quantum well layers, in the c-axis direction is not more than 10 Å, and the half band width of an emission spectrum can be reduced.

Thus, dislocation-free m-plane group III nitride semiconductors having planar stacking interfaces can be grown. However, the offset angle of the major surface of the GaN monocrystalline substrate 1 is preferably set within ±1° (more preferably within ±0.3°). If GaN semiconductor layers are grown on an m-plane GaN monocrystalline substrate having an offset angle set to 2°, for example, GaN crystals may be grown in the form of terraces and a planar surface state may not be obtained dissimilarly to the case of setting the offset angle within ±1°.

Group III nitride semiconductors crystal-gown on the GaN monocrystalline substrate having the major surface defined by an m-plane are grown with major growth surfaces defined by m-planes. If the group III nitride semiconductors are crystal-grown with major surfaces defined by c-planes, luminous efficiency in the light emitting layer 10 may be deteriorated due to influence by polarization in the c-axis direction. When the major growth surfaces are defined by m-planes which are nonpolar planes, on the other hand, polarization in the quantum well layers is suppressed, and the luminous efficiency is increased. Thus, reduction of a threshold and increase in slope efficiency can be implemented. Current dependency of the emission wavelength is suppressed due to small polarization, and a stable oscillation wavelength can be implemented.

Further, anisotropy in physical properties is caused in the c-axis direction and the a-axis direction due to the major surfaces defined by m-planes. In addition, biaxial stress resulting from lattice strain is caused in the light emitting layer 10 (active layer) containing In. Consequently, state density of a valence band is reduced, population inversion is easily attained and a gain is reinforced as compared with a case of defining the major surfaces by c-planes, and laser characteristics are improved.

The major surfaces of crystal growth are so defined by m-planes that group III nitride semiconductor crystals can be extremely stably grown, and crystallinity can be further improved as compared with a case of defining the major crystal growth surfaces by c-planes or a-planes. Thus, a high-performance laser diode can be prepared.

The light emitting layer 10 is formed by group III nitride semiconductors grown with major crystal growth surfaces defined by m-planes, and hence the light emitted therefrom is polarized in an a-axis direction, i.e., a direction parallel to the m-planes, and travels in a c-axis direction in the case of a TE mode. Therefore, the major crystal growth surface of the semiconductor laser diode 70 is parallel to the direction of polarization, and a stripe direction, i.e., the direction of a waveguide is set parallel to the traveling direction of the light. Thus, oscillation of the TE mode can be easily caused, and a threshold current for causing laser oscillation can be reduced.

According to the embodiment, the GaN monocrystalline substrate is employed as the substrate 1, whereby the group III nitride semiconductor multilayer structure 2 can have high crystal quality with a small number of defects. Consequently, a high-performance laser diode can be implemented.

Further, the group III nitride semiconductor structure 2 grown on the generally dislocation-free GaN monocrystalline substrate can be formed by excellent crystals having neither stacking faults nor threading dislocations from a regrowth surface (m-plane) of the substrate 1. Thus, characteristic deterioration such as reduction in luminous efficiency resulting from defects can be suppressed.

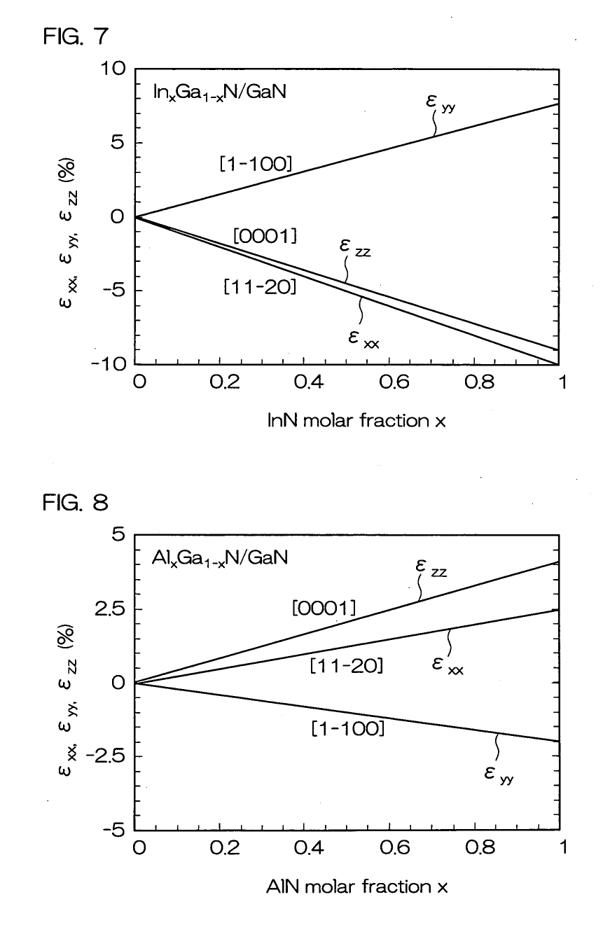

FIG. 7 is a graph showing InN molar fraction dependency of in-plane compressive strain in an InGaN layer coherently grown on an m-plane GaN substrate. The quantity (%) of negative strain expresses compressive strain, and the quantity of positive strain expresses tensile strain. It is understood from FIG. 7 that a-axis direction compressive strain εₓₓ and c-axis direction compressive strain ε_{zz} as well as m-axis direction tensile strain ε_{yy} are increased when the InN molar fraction (i.e., the composition of In) is increased. The a-axis direction compressive strain εₓₓ results from the fact that the a-axis lattice constant of InGaN in a strain-free state is greater than that of GaN. It is understood that lattice mismatching is increased following increase in the In composition, and hence the a-axis direction compressive strain εₓₓ is increased accordingly.

On the other hand, FIG. 8 is a graph showing AlN molar fraction dependency of in-plane compressive strain in an AlGaN layer coherently grown on the m-plane GaN substrate. The quantity (%) of negative strain expresses compressive strain, and the quantity of positive strain expresses tensile strain. It is understood from FIG. 8 that a-axis direction tensile strain εₓₓ and c-axis direction tensile strain ε_{zz} as well as m-axis direction compressive strain ε_{yy} are increased when the AlN molar fraction (i.e., the composition of Al) is increased. The a-axis direction tensile strain εₓₓ results from the fact that the a-axis lattice constant of AlGaN in a strain-free state is smaller than that of GaN (and hence smaller than the a-axis lattice constant of InGaN). It is understood that lattice mismatching is increased following increase in the Al composition, and hence the a-axis direction tensile strain εₓₓ is increased accordingly.

According to the embodiment, the light emitting layer 10 has the multiple-quantum well structure obtained by alternately stacking the quantum well layers 221 formed by InGaN layers and the barrier layers 222 formed by AlGaN layers, as hereinabove described. The layers constituting the group III nitride semiconductor multilayer structure 2 are coherently grown with respect to the m-plane GaN substrate 1. Therefore, compressive strain is caused in the InGaN layers and tensile strain is caused in the AlGaN layers in relation to the a-axis direction. However, the InGaN layers and the AlGaN layers are alternately stacked in the light emitting layer 10, and hence compressive stress in the quantum well layers 221 formed by InGaN layers is relaxed by the barrier layers 222 formed by AlGaN layers. In other words, the barrier layers 222 function as strain compensation layers relaxing compressive stress in the quantum well layers 221. Thus, crystal defects resulting from compressive strain can be suppressed, whereby the quantum well layers 221 can have excellent crystallinity with small numbers of defects. More specifically, formation of striped crystal defects parallel to the a-axis direction observed in a case of forming an InGaN layer on an m-plane GaN substrate can be suppressed or eliminated. Thus, regions capable of contributing to light emission are increased in the quantum well layers 221, whereby the luminous efficiency is improved, and an oscillation threshold can be reduced accordingly.

According to the embodiment, further, the thickness of each quantum well layer 221 is set to not more than 100 Å as hereinabove described, whereby improvement of the luminous efficiency resulting from the quantum effect can also be expected. The quantum well layer 221 has the small thickness allowing the quantum effect and a high-quality crystal state with a small number of crystal defects, whereby excellent luminous efficiency can be implemented.

In addition, the thickness of each barrier layer 222 is set to 3 nm to 8 nm and the Al composition in the barrier layer 222 is set to not more than 5%, whereby an average refractive index around the light emitting layer 10 is increased. Thus, an excellent light confining effect can be implemented, and the threshold current is further reduced.

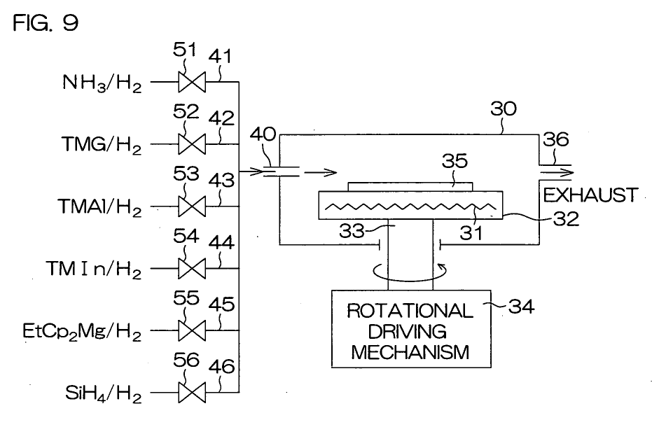

FIG. 9 is a schematic diagram for illustrating the structure of a treating apparatus for growing the layers constituting the group III nitride semiconductor multilayer structure 2. A susceptor 32 storing a heater 31 is disposed in a treating chamber 30. The susceptor 32 is coupled to a rotating shaft 33, which in turn is rotated by a rotational driving mechanism 34 disposed outside the treating chamber 30. Thus, the susceptor 32 holds a wafer 35 to be treated, so that the wafer 35 can be heated to a prescribed temperature and rotated in the treating chamber 30. The wafer 35 is a GaN monocrystalline wafer constituting the aforementioned GaN monocrystalline substrate 1.

An exhaust pipe 36 is connected to the treating chamber 30. The exhaust pipe 36 is connected to exhaust equipment such as a rotary pump. Thus, the pressure in the treating chamber 30 is set to 1/10 atm to ordinary pressure, and the atmosphere in the treating chamber 30 is regularly exhausted.

On the other hand, a source gas feed passage 40 for feeding source gas toward the surface of the wafer 35 held by the susceptor 32 is introduced into the treating chamber 30. A nitrogen material pipe 41 feeding ammonia as nitrogen source gas, a gallium material pipe 42 feeding trimethyl gallium (TMG) as gallium source gas, an aluminum material pipe 43 feeding trimethyl aluminum (TMAl) as aluminum source gas, an indium material pipe 44 feeding trimethyl indium (TMIn) as indium source gas, a magnesium material pipe 45 feeding ethylcyclopentadienyl magnesium (EtCp₂Mg) as magnesium source gas and a silicon material pipe 46 feeding silane (SiH₄) as source gas of silicon are connected to the source gas feed passage 40. Valves 51 to 56 are interposed in the material pipes 41 to 46 respectively. Each source gas is fed along with the carrier gas consisting of hydrogen and/or nitrogen.

For example, a GaN monocrystalline wafer having a major surface defined by an m-plane is held by the susceptor 32 as the wafer 35. In this state, the nitrogen material valve 51 is opened while the valves 52 to 56 are kept closed, so that the carrier gas and ammonia gas (nitrogen source gas) are fed into the treating chamber 30. Further, the heater 31 is electrified, and the wafer temperature is increased to 1000° C. to 1100° C. (1050° C., for example). Thus, GaN semiconductors can be grown without roughening the surface.

After waiting until the wafer temperature reaches 1000° C. to 1100° C., the nitrogen material valve 51, the gallium material valve 52 and the silicon material valve 56 are opened. Thus, ammonia, trimethyl gallium and silane are fed from the source gas feed passage 40 along with the carrier gas. Consequently, the n-type GaN contact layer 13 formed of a GaN layer doped with silicon is grown on the surface of the wafer 35.

Then, the aluminum material valve 53 is opened in addition to the nitrogen material valve 51, the gallium material valve 52 and the silicon material valve 56. Thus, ammonia, trimethyl gallium, silane and trimethyl aluminum are fed from the source gas feed passage 40 along with the carrier gas. Consequently, the n-type AlGaN cladding layer 14 is epitaxially grown on the n-type GaN contact layer 13. At this time, the flow rate of each source gas (particularly the aluminum source gas) is adjusted so that the Al composition in the AlGaN cladding layer 14 is not more than 5%.

Then, the aluminum material valve 53 is closed, and the nitrogen material valve 51, the gallium material valve 52, the indium material valve 54 and the silicon material valve 56 are opened. Thus, ammonia, trimethyl gallium, trimethyl indium and silane are fed from the source gas feed passage 40 along with the carrier gas. Consequently, the n-type InGaN guide layer 15 is epitaxially grown on the n-type AlGaN cladding layer 14. In the formation of the n-type InGaN guide layer 15, the temperature of the wafer 35 is preferably set to 800° C. to 900° C. (850° C., for example).

Then, the silicon material valve 56 is closed, and the light emitting layer 10 (active layer) having the multiple-quantum well structure is grown. The light emitting layer 10 can be grown by alternately carrying out a step of growing a quantum well layer 221 formed of an InGaN layer by opening the nitrogen material valve 51, the gallium material valve 52 and the indium material valve 54 for feeding ammonia, trimethyl gallium and trimethyl indium to the wafer 35, and a step of growing a barrier layer 222 formed of an AlGaN layer by closing the indium material valve 54 and opening the nitrogen material valve 51, the gallium material valve 52 and the aluminum material valve 53 for feeding ammonia, trimethyl gallium and trimethyl aluminum to the wafer 35. For example, a barrier layer 222 is formed at first, and a quantum well layer 221 is formed thereon. The operation is repetitively performed twice, for example, and a barrier layer 222 is finally formed. In the formation of the light emitting layer 10, the temperature of the wafer 35 is preferably set to 700° C. to 800° C. (730° C., for example), for example. At this time, the growth pressure is preferably set to not less than 700 torr, whereby heat resistance can be improved.

Then, the aluminum material valve 53 is closed, and the nitrogen material valve 51, the gallium material valve 52, the indium material valve 54 and the magnesium material valve 55 are opened. Thus, ammonia, trimethyl gallium, trimethyl indium and ethylcyclopentadienyl magnesium are fed toward the wafer 35, to form the guide layer 16 formed of a p-type InGaN layer doped with magnesium. In the formation of the p-type InGaN guide layer 16, the temperature of the wafer 35 is preferably set to 800° C. to 900° C. (850° C., for example).

Then, the p-type AlGaN electron blocking layer 17 is formed. In other words, the nitrogen material valve 51, the gallium material valve 52, the aluminum material valve 53 and the magnesium material valve 55 are opened, and the remaining valves 54 and 56 are closed. Thus, ammonia, trimethyl gallium, trimethyl aluminum and ethylcyclopentadienyl magnesium are fed toward the wafer 35, to form the p-type AlGaN electron blocking layer 17 formed of an AlGaN layer doped with magnesium. In the formation of the p-type AlGaN electron blocking layer 17, the temperature of the wafer 35 is preferably set to 900° C. to 1100° C. (1000° C., for example).

Then, the p-type AlGaN cladding layer 18 is formed. In other words, the nitrogen material valve 51, the gallium material valve 52, the aluminum material valve 53 and the magnesium material valve 55 are opened, and the remaining valves 54 and 56 are closed. Thus, ammonia, trimethyl gallium, trimethyl aluminum and ethylcyclopentadienyl magnesium are fed toward the wafer 35, to form the cladding layer 48 formed of a p-type AlGaN layer doped with magnesium. In the formation of the p-type AlGaN cladding layer 18, the temperature of the wafer 35 is preferably set to 900° C. to 1100° C. (1000° C., for example). Further, the flow rate of each source gas (particularly the aluminum source gas) is adjusted so that the Al composition in the p-type AlGaN cladding layer 18 is not more than 5%.

Then, the p-type contact layer 19 is formed. In other words, the nitrogen material valve 51, the gallium material valve 52 and the magnesium material valve 55 are opened, and the remaining valves 53, 54 and 56 are closed. Thus, ammonia, trimethyl gallium and ethylcyclopentadienyl magnesium are fed toward the wafer 35, to form the p-type GaN contact layer 19 formed of a GaN layer doped with magnesium. In the formation of the p-type GaN contact layer 19, the temperature of the wafer 35 is preferably set to 900° C. to 1100° C. (1000° C., for example).

The layers constituting the p-type semiconductor layered portion 12 are preferably crystal-grown at an average growth temperature of not more than 1000° C. Thus, thermal damage on the light emitting layer 10 can be reduced.

When the layers 10 and 13 to 19 constituting the group III nitride semiconductor multilayer structure 2 are grown on the wafer 35 (the GaN monocrystalline substrate 1), a V/III ratio indicating the ratio of the molar fraction of the nitrogen material (ammonia) to the molar fraction of the gallium material (trimethyl gallium) fed to the wafer 35 in the treating chamber 30 is maintained at a high value of not less than 1000 (preferably not less than 3000) in the growth of each layer. More specifically, the average of the V/III ratios is preferably not less than 1000 from the n-type cladding layer 14 up to the uppermost p-type contact layer 19. Thus, excellent crystals having small numbers of point defects can be obtained in all of the n-type cladding layer 14, the light emitting layer 10 and the p-type cladding layer 18.

According to the embodiment, the group III nitride semiconductor layer 2 having the major surface defined by an m-plane or the like is grown in a dislocation-free state in a planar manner by employing the aforementioned high V/III ratio and without interposing a buffer layer between the GaN monocrystalline substrate 1 and the group III nitride semiconductor multilayer structure 2. The group III nitride semiconductor multilayer structure 2 has neither stacking faults nor threading dislocations formed from the major surface of the GaN monocrystalline substrate 1.

When the group III nitride semiconductor multilayer structure 2 is grown on the wafer 35 in the aforementioned manner, the wafer 35 is transferred to an etching apparatus, and the ridge stripe 20 is formed by partially removing the p-type semiconductor layered portion 12 by dry etching such as plasma etching, for example. The ridge stripe 20 is formed to be parallel to the c-axis direction.

After the formation of the ridge stripe 20, the insulating layer 6 is formed. The insulating layer 6 is formed through a lift-off step, for example. In other words, the insulating layer 6 can be formed by forming a striped mask, thereafter forming an insulator thin film to entirely cover the p-type AlGaN cladding layer 18 and the p-type GaN contact layer 19 and thereafter lifting off the insulator thin film for exposing the p-type GaN contact layer 19.

Then, the p-type electrode 4 in ohmic contact with the p-type GaN contact layer 19 and the n-type electrode 3 in ohmic contact with the substrate 1 are formed. The electrodes 3 and 4 can be formed by resistance heating or a metal vapor deposition apparatus employing an electron beam, for example.

When the p-type electrode 4 is formed of a Pt/Au film, a Pt film and an Au film are successively evaporated to entirely cover the p-type GaN contact layer 19 exposed from the insulating layer 6 and the insulating layer 6 by resistance heating or a metal vapor deposition apparatus employing an electron beam, for example.

After the Au film is evaporated to form an electrode material constituting the p-type electrode 4 formed of the Pt/Au film, a photoresist film is formed to cover the overall Au film. Then, the photoresist film is prebaked at a temperature of not more than 400° C., for example, and preferably not more than 200° C. The photoresist film is exposed and developed through a striped mask, and thereafter post-baked at a temperature of not more than 400° C., for example, and preferably not more than 200° C.

Thereafter the Pt/Au film is etched through the developed photoresist film and the photoresist film is lifted off, to form the p-type electrode 4.

After the formation of the p-type electrode 4, the p-type electrode 4 is annealed in an oxygen-containing atmosphere (in the atmosphere, for example) at 200° C. Thereafter the n-type electrode 3 in ohmic contact with the substrate 1 is formed.

The next step is division into each individual device. In other words, each device constituting the semiconductor laser diode is cut out by cleaving the wafer 35 in a direction parallel to the ridge stripe 20 and a direction perpendicular thereto. When the cavity end faces 21 and 22 are defined by c-planes, the wafer 35 is cleaved in the direction parallel to the ridge stripe 20 along the a-plane. Further, the wafer 35 is cleaved in the direction perpendicular to the ridge stripe 20 along the c-plane. Thus, the cavity end face 21 defined by the +c-plane and the cavity end face 22 defined by the −c-plane are formed. When the cavity end faces 21 and 22 are defined by a-planes, on the other hand, the wafer 35 is cleaved in the direction parallel to the ridge stripe 20 along the c-plane. Further, the wafer 35 is cleaved in the direction perpendicular to the ridge stripe 20 along the a-plane. Thus, the cavity end faces 21 and 22 defined by a-planes are formed.

In the case of performing the cleavage, the sum of the thickness of the substrate 1 and the thickness of the semiconductor multilayer structure 2 in the growth direction is preferably not more than 200 μm, and hence the substrate 1 may be previously mechanically or chemically polished. More specifically, scribing lines are applied to the surface of the semiconductor multilayer structure 2 with a diamond pen, or scribing lines are formed in the semiconductors by focusing a laser beam on the interior of the semiconductor multilayer structure 2. The scribing lines denote damages applied to the semiconductors in a direction along the cleavage. Then, the wafer 35 is cleaved by externally applying stress along the scribing lines or the like. The wafer 35 can be cleaved with excellent symmetry along c-planes or a-planes.

Then, the aforementioned insulating films 23 and 24 are formed on the cavity end faces 21 and 22 respectively. The insulating films 23 and 24 can be formed by electron cyclotron resonance (ECR) film formation, for example.

The semiconductor laser diode 70 obtained in the aforementioned manner is placed on bonding paste applied to a land (not shown) of a wiring circuit board, for example, and heated to a temperature of not more than 400° C., for example, more preferably not more than 200° C. and pressurized, to be mounted on the wiring circuit board.

When constituted of a Pt/Au film, the p-type electrode 4 is annealed at the temperature of 200° C. after the formation, as hereinabove described.

A group III nitride semiconductor having a major surface defined by a c-plane and a group III nitride semiconductor having a major surface defined by a nonpolar plane or a semipolar plane have different atomic compositions on the surfaces. Therefore, the group III nitride semiconductors and an electrode material are different in reactivity from one another in annealing. For example, proper values of a temperature (annealing temperature) for the annealing are different. When an electrode material containing Pt is formed on a p-type GaN layer having a major growth surface defined by an m-plane and the material is annealed, a proper annealing temperature is 200° C., and a contact property of the electrode with respect to the p-type GaN layer may be reduced if the annealing temperature exceeds 400° C.

In the aforementioned manufacturing steps, the p-type electrode 4 is annealed at the temperature of 200° C. after the formation thereof, whereby the p-type electrode 4 can be remarkably excellently brought into ohmic contact with the p-type GaN contact layer 19. Consequently, excellent electrical characteristics can be attained in the semiconductor laser diode 70, whereby the laser characteristics can be improved.

After the formation of the electrode material constituting the p-type electrode 4, the process temperature to which the electrode material (including the p-type electrode 4) is exposed is maintained at not more than 400° C. More specifically, the process temperature is maintained at not more than 400° C., for example, and preferably not more than 200° C., in the steps of prebaking and post-baking the photoresist film after the formation of the electrode material. Therefore, reduction in the ohmic property of the p-type electrode 4 excellently in ohmic contact with the p-type GaN contact layer 19 can be suppressed. Consequently, reduction in the electrical characteristics can be suppressed in the semiconductor laser diode 70.

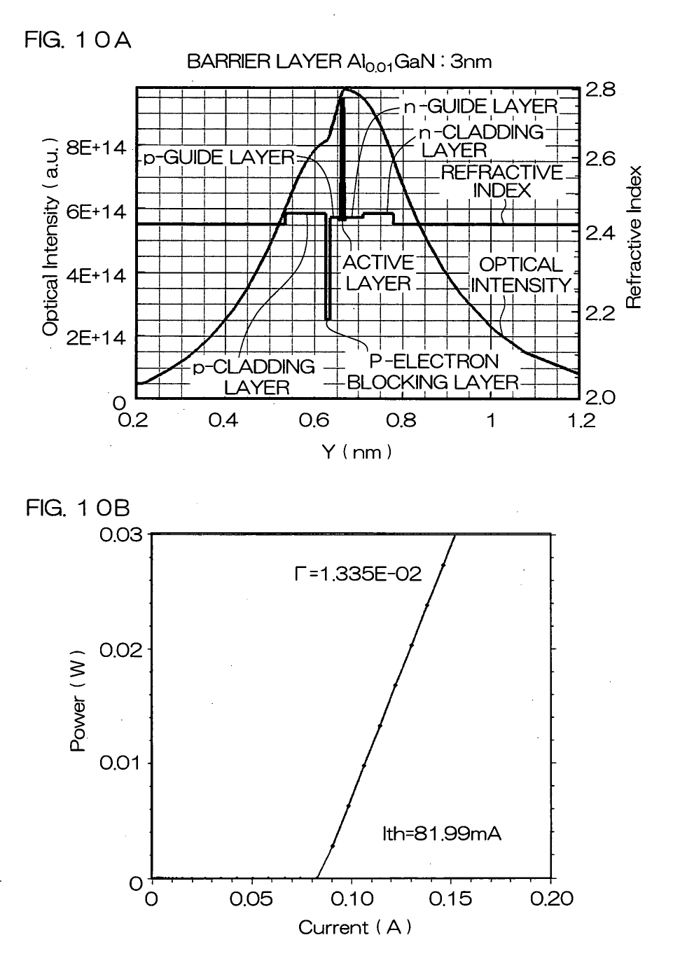

FIGS. 10A and 10B, 11A and 11B, 12A and 12B, and 13A and 13B show results of simulation made by the inventors of the application. More specifically, FIGS. 10A and 10B, 11A and 11B, 12A and 12B and 13A and 13B show results of calculations made while varying the thickness of each AlGaN barrier layer 222. It was assumed that the guide layers 15 and 16 were composed of In_{0.01}GaN, and the barrier layer 222 was composed of Al_{0.01}GaN.

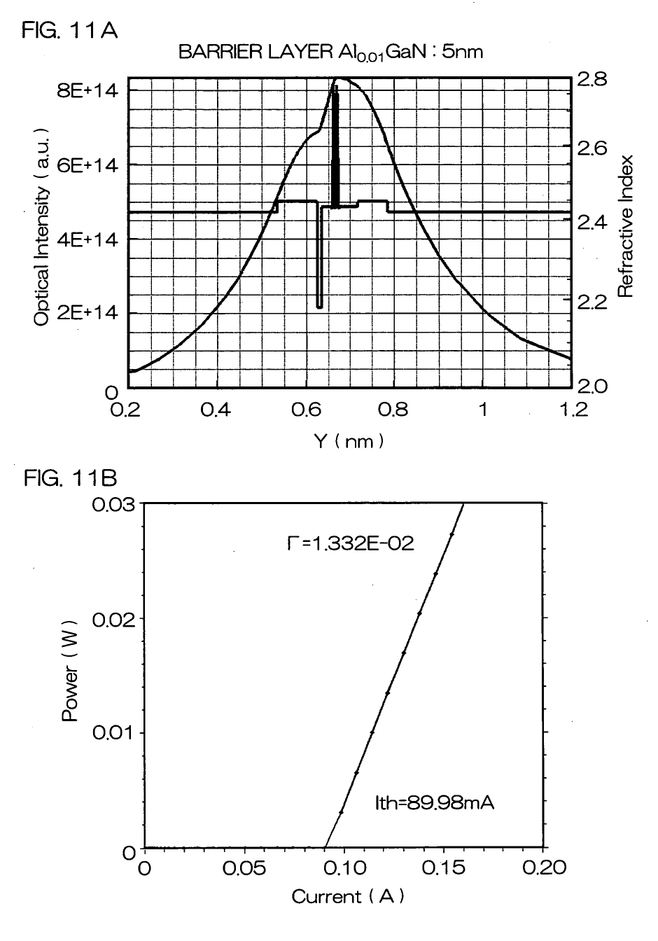

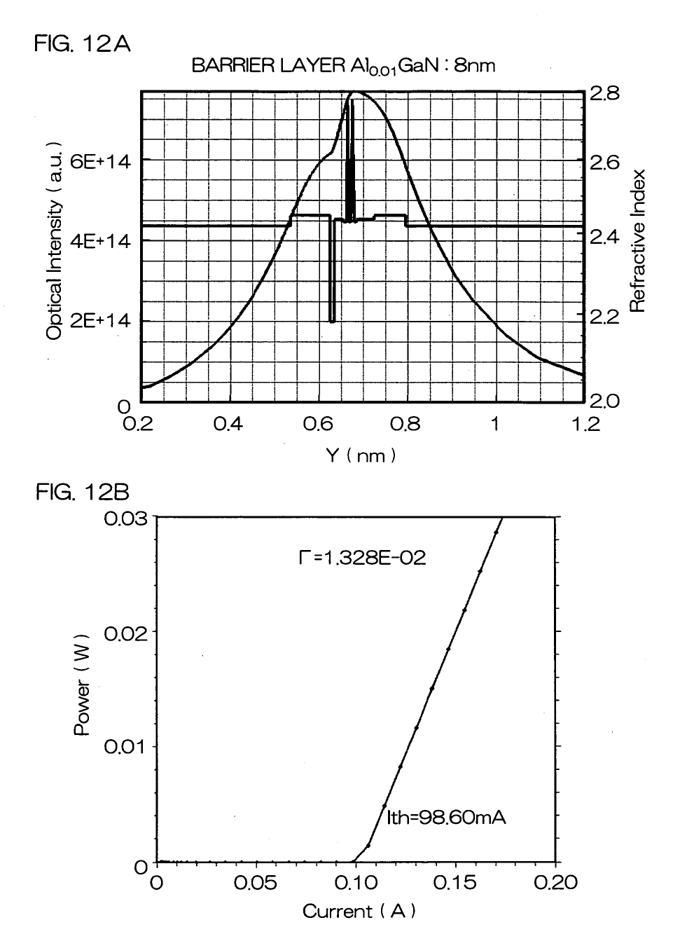

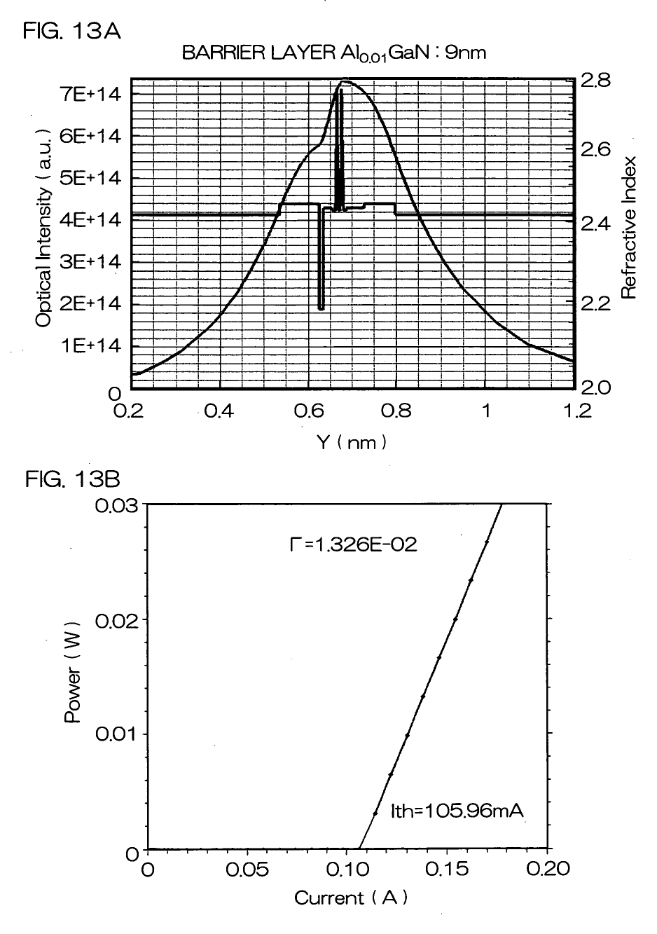

FIGS. 10A and 10B show results of calculations in a case of setting the thickness of the barrier layer 222 to 3 nm. FIGS. 11A and 11B show results of calculations in a case of setting the thickness of the barrier layer 222 to 5 nm. FIGS. 12A and 12B show results of calculations in a case of setting the thickness of the barrier layer 222 to 8 nm. FIGS. 13A and 13B show results of calculations in a case of setting the thickness of the barrier layer 222 to 9 nm.

FIGS. 10A, 11A, 12A and 13A show depths (Y μm) from the surface of the group III nitride semiconductor multilayer structure 2 on the axes of abscissas while showing optical density and refractive indices on the axes of ordinates, to express optical intensity distributions and refractive index distributions. The positions of the layers are shown in FIG. 10A.

On the other hand, FIGS. 10B, 11B, 12B and 13B show forward currents on the axes of abscissas while showing optical outputs (power) on the axes of ordinates, to express current-optical output characteristics.

Threshold currents Ith and confinement coefficients ┌ (ratios of light confined in the light emitting layer (active layer)) obtained by the calculations are as follows:

When the thickness of the AlGaN barrier layer is 3 nm (FIGS. 10A and 10B):

Ith=81.99 mA, ┌=1.335×10⁻²

When the thickness of the AlGaN barrier layer is 4 nm:

Ith=83.39 mA, ┌=1.333×10⁻²

When the thickness of the AlGaN barrier layer is 5 nm (FIGS. 11A and 11B):

Ith=89.98 mA, ┌=1.332×10⁻²

When the thickness of the AlGaN barrier layer is 6 nm:

Ith=90.87 mA, ┌=1.330×10⁻²

When the thickness of the AlGaN barrier layer is 7 nm:

Ith=97.96 mA, ┌=1.330×10⁻²

When the thickness of the AlGaN barrier layer is 8 nm (FIGS. 12A and 12B):

Ith=98.60 mA, ┌=1.328×10⁻²

When the thickness of the AlGaN barrier layer is 9 nm (FIGS. 13A and 13B: comparative example):

Ith=105.96 mA, ┌=1.326×10⁻²

When the thickness of the AlGaN barrier layer is 10 nm (comparative example):

Ith=110 mA, ┌=1.324×10⁻²

When the thickness of the AlGaN barrier layer is 11 nm (comparative example):

Ith=113.97 mA, ┌=1.322×10⁻²

It is understood from the results that the light confining effect is increased when the thickness of the barrier layer 222 is increased, while the threshold current is also increased. The threshold current forming the standard of continuous wave oscillation is 100 mA, and hence it is understood that an excellent light confining effect is attained and a laser diode capable of continuous wave oscillation can be implemented by setting the thickness of the barrier layer 222 to not more than 8 nm.

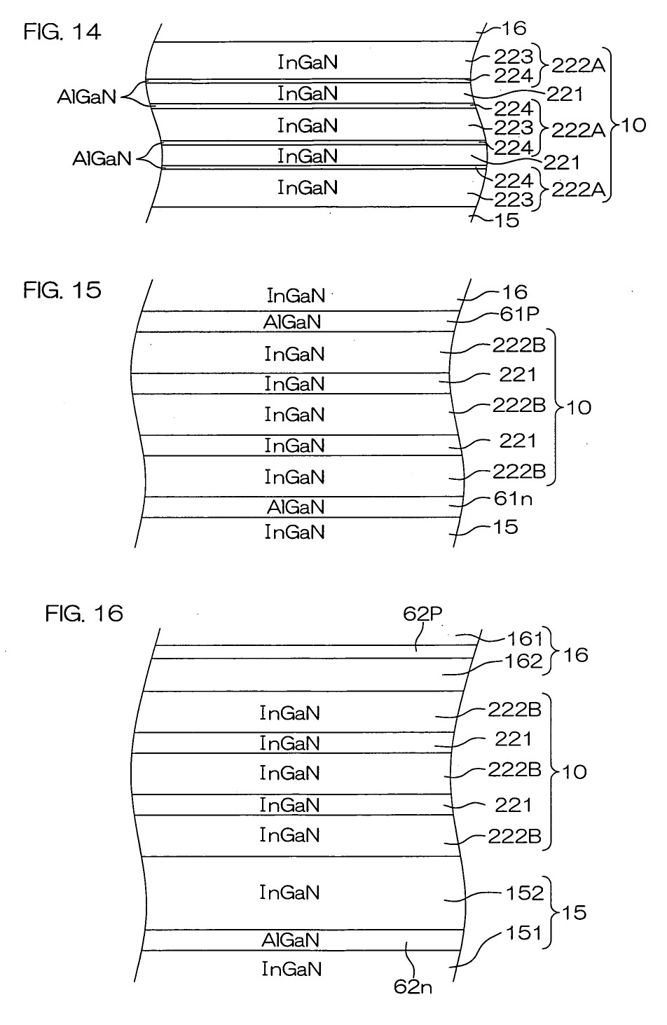

FIG. 14 is a schematic sectional view showing the structure of a light emitting layer of a semiconductor laser diode according to a second embodiment of the present invention. The semiconductor laser diode according to this embodiment is described also with reference to FIGS. 1 to 3.

A light emitting layer 10 according to the embodiment is common to that in the first embodiment in a point that the same has a multiple-quantum well structure obtained by alternately stacking quantum well layers 221 and barrier layers 222A, while the structure of each barrier layer 222A is different. In other words, each barrier layer 222A has an InGaN layer 223 and a strain compensation layer 224 interposed between the InGaN layer 223 and the corresponding quantum well layer 221. In other words, the strain compensation layer 224 is in contact with the quantum well layer 221.

The strain compensation layer 224 is formed by an AlGaN layer. The quantum well layer 221 has a relatively large In composition (not less than 5%, for example), while the InGaN layer 223 forming the barrier layer 222A has a relatively small In composition (less than 5%, for example). Therefore, the band gap of the InGaN layer 223 is larger than that of the quantum well layer 221.

On the other hand, a-axis direction compressive strain εₓₓ in the InGaN layer 223 having a small In composition is smaller than that in the quantum well layer 221 having a large In composition, as understood from FIG. 7. The strain compensation layer 224 formed of the AlGaN layer (see FIG. 8) causing a-axis direction tensile strain is interposed between the InGaN layer 223 and the quantum well layer 221. Therefore, a-axis direction compressive stress in the quantum well layer 221 is relaxed mainly by action of the strain compensation layer 224, whereby crystal defects in the quantum well layer 221 can be suppressed and luminous efficiency can be improved, similarly to the case of the first embodiment.

The strain compensation layer 224 has an Al composition of 4%, and a thickness of about 1 nm, for example.

Manufacturing steps for the semiconductor laser diode according to the present embodiment are similar to those for the semiconductor laser diode according to the first embodiment, and layers constituting a group III nitride semiconductor multilayer structure 2 can be formed by the apparatus shown in FIG. 9. However, the light emitting layer 10 is formed through the following steps:

The light emitting layer 10 is grown through the steps of forming an InGaN quantum well layer 221, forming an InGaN layer 223 and forming an AlGaN strain compensation layer 224. More specifically, the InGaN layer 223 is formed on an n-type InGaN guide layer 15, the AlGaN strain compensation layer 224 is formed thereon, the InGaN quantum well layer 221 is formed thereon, and the AlGaN strain compensation layer 224 is formed thereon. Thereafter InGaN layers 223, AlGaN strain compensation layers 224, InGaN quantum well layers 221 and AlGaN strain compensation layers 224 are formed in this order a plurality of times, to form a necessary number of quantum well layers 221. Then, an InGaN layer 223 is finally formed.

The InGaN quantum well layer 221 and the InGaN layer 223 can be formed by opening the nitrogen material valve 51, the gallium material valve 52 and the indium material valve 54 while closing the remaining source gas valves 53, 55 and 56, for feeding ammonia, trimethyl gallium and trimethyl indium to the wafer 35. However, the flow rate of each source gas (particularly the indium source gas) for growing the layers is adjusted so that the In composition in the InGaN layer 223 is smaller than that in the InGaN quantum well layer 221.

The AlGaN strain compensation layer 224 can be formed by opening the nitrogen material valve 51, the gallium material valve 52 and the aluminum material valve 53 while closing the remaining source gas valves 54, 55 and 56 for feeding ammonia, trimethyl gallium and trimethyl aluminum to the wafer 35.

FIG. 15 is a schematic sectional view showing a structure around a light emitting layer of a semiconductor laser diode according to a third embodiment of the present invention. The semiconductor laser diode according to this embodiment is described also with reference to FIGS. 1 to 3.

A light emitting layer 10 according to the embodiment is common to those in the aforementioned first and second embodiments in a point that the same has a multiple-quantum well structure obtained by alternately stacking quantum well layers 221 and barrier layers 222B. However, each barrier layer 222B is formed by a single InGaN layer (having a thickness of 9 nm, for example), and the InGaN layer is in contact with the corresponding quantum well layer 221. The quantum well layer 221 has a relatively large In composition (not less than 5%, for example), while the InGaN layer constituting the barrier layer 222B has a relatively small In composition (less than 5%, for example) Therefore, the band gap of the barrier layer 222B is larger than that of the quantum well layer 221.

According to the embodiment, on the other hand, a strain compensation layer 61n consisting of an n-type AlGaN layer and a strain compensation layer 61p consisting of a p-type AlGaN layer are provided on an n-type guide layer 15 and a p-type guide layer 16 which are adjacent layers adjacent to the light emitting layer 10 respectively, to be in contact with the light emitting layer 10. More specifically, the lowermost barrier layer 222B (on a side closer to a substrate 1) of the light emitting layer 10 and the n-type AlGaN strain compensation layer 61n are in contact with each other. Further, the uppermost barrier layer 222B (on a side closer to a ridge stripe 20) of the light emitting layer 10 and the p-type AlGaN strain compensation layer 61p are in contact with each other.

According to such a structure, a-axis direction compressive stress in the quantum well layers 221 is relaxed due to action of the strain compensation layers 61n and 61p in contact with the uppermost and lowermost layers of the light emitting layer 10, whereby crystal defects in the quantum well layers 221 can be suppressed and luminous efficiency can be improved, similarly to the cases of the first and second embodiments.

The n-type strain compensation layer 61n provided between the light emitting layer 10 and the GaN substrate 1 more contributes to the reduction of compressive stress in the quantum well layers 221 than the p-type strain compensation layer 61p provided on the light emitting layer 10. This is because the n-type strain compensation layer 61n is grown in advance of the light emitting layer 10. If a sufficient stress relaxation effect is attained with only the n-type strain compensation layer 61n, therefore, the p-type strain compensation layer 61p may be omitted.

Manufacturing steps for the semiconductor laser diode according to the present embodiment are similar to those for the semiconductor laser diode according to the first embodiment, and layers constituting the group III nitride semiconductor multilayer structure 2 can be formed by the apparatus shown in FIG. 9. However, the n-type AlGaN strain compensation layer 61n is formed after formation of an InGaN layer portion of the n-type guide layer 15, and the light emitting layer 10 is formed thereon. After the formation of the light emitting layer 10, the p-type AlGaN strain compensation layer 61p is formed, and an InGaN layer portion of the p-type guide layer 16 is formed thereon.

In the formation of the n-type AlGaN strain compensation layer 61n, the nitrogen material valve 51, the gallium material valve 52, the aluminum material valve 53 and the silicon material valve 56 are opened, and the remaining source gas valves 54 and 55 are closed. Thus, ammonia, trimethyl gallium, trimethyl aluminum and silane are fed from the source gas passage 40 along with the carrier gas. Consequently, the n-type AlGaN strain compensation layer 61n is epitaxially grown on the n-type InGaN guide layer 15.

In the formation of the p-type AlGaN strain compensation layer 61p, the nitrogen material valve 51, the gallium material valve 52, the aluminum material valve 53 and the magnesium material valve 55 are opened, and the remaining source gas valves 54 and 56 are closed. Thus, ammonia, trimethyl gallium, trimethyl aluminum and ethylcyclopentadienyl magnesium are fed from the source gas feed passage 40 along with the carrier gas. Consequently, the p-type AlGaN strain compensation layer 61p is epitaxially grown on the light emitting layer 10.

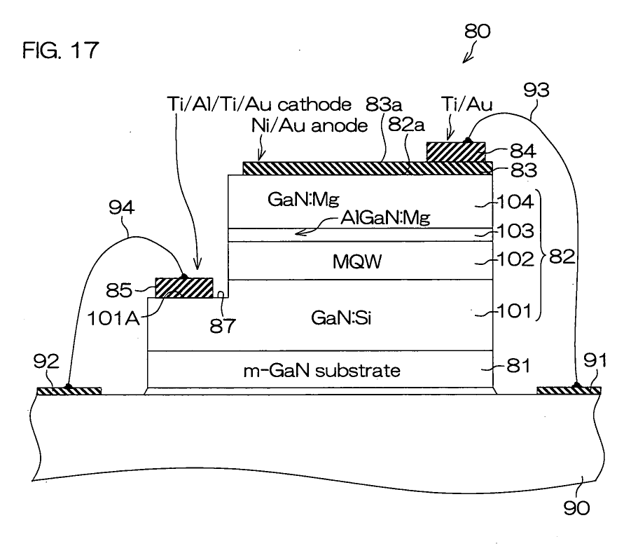

FIG. 16 is a schematic sectional view showing a structure around a light emitting layer of a semiconductor laser diode according to a fourth embodiment of the present invention. Referring to FIG. 16, portions corresponding to those shown in FIG. 15 are denoted by the same reference numerals as those in FIG. 15. The semiconductor laser diode according to this embodiment is described also with reference to FIGS. 1 to 3.

According to the embodiment, an n-type strain compensation layer 62n is interposed in a layer-thickness intermediate position of an n-type guide layer 15 provided between a light emitting layer 10 and a GaN substrate 1. In other words, the n-type guide layer 15 is divided into a first InGaN portion 151 closer to an n-type AlGaN cladding layer 14 and a second InGaN portion 152 closer to the light emitting layer 10, and the n-type AlGaN strain compensation layer 62n is interposed between the first and second InGaN portions 151 and 152.

Further, a p-type strain compensation layer 62p is interposed in a layer-thickness intermediate position of a p-type guide layer 16 provided on the light emitting layer 10. In other words, the p-type guide layer 15 is divided into a first InGaN portion 161 closer to a p-type AlGaN cladding layer 18 and a second InGaN portion 162 closer to the light emitting layer 10, and the p-type AlGaN strain compensation layer 62p is interposed between the first and second InGaN portions 161 and 162.

According to such a structure, a-axis direction compressive stress in quantum well layers 221 is relaxed due to action of the strain compensation layers 62n and 62p, whereby crystal defects in the quantum well layers 221 can be suppressed and luminous efficiency can be improved, similarly to the cases of the first to third embodiments.

In the n-type guide layer 15, the thickness of the first InGaN portion 151 is set to about 50 nm, for example, and the thickness of the second InGaN portion 152 is set to about 50 nm, for example. Similarly, the thickness of the first InGaN portion 161 is set to about 50 nm, for example, and the thickness of the second InGaN portion 162 is set to about 50 nm, for example, in the p-type guide layer 16.

Methods of forming the AlGaN strain compensation layers 62n and 62p are similar to those for the AlGaN strain compensation layers 61n and 61p in the aforementioned third embodiment, and hence redundant description is omitted.

The n-type strain compensation layer 62n provided between the light emitting layer 10 and the GaN substrate 1 more contributes to the reduction of compressive stress in the quantum well layers 221 than the p-type strain compensation layer 62p provided above the light emitting layer 10. This is because the n-type strain compensation layer 62n is grown in advance of the light emitting layer 10. If a sufficient stress relaxation effect is attained with only the n-type strain compensation layer 62n, therefore, the p-type strain compensation layer 62p may be omitted.

FIG. 17 is a schematic sectional view for illustrating the structure of a light emitting diode according to a fifth embodiment of the present invention. A light emitting diode 80 has a device body obtained by growing a group III nitride semiconductor layered portion 82 forming a group III nitride semiconductor multilayer structure on a GaN (gallium nitride) monocrystalline substrate 81. The group III nitride semiconductor layered portion 82 has a multilayer structure obtained by successively stacking an n-type contact layer 101, a multiple-quantum well (MQW) layer 102 as a light emitting layer, a p-type electron blocking layer 103 and a p-type contact layer 104 from the side closer to the GaN monocrystalline substrate 81. A p-type electrode (anodic electrode) 83 as a transparent electrode is formed on the surface of the p-type contact layer 104, and a connecting portion 84 for wire connection is bonded to a part of the p-type electrode 83. An n-type electrode (cathodic electrode) 85 is bonded to the n-type contact layer 101. Thus, a light emitting diode structure is formed. The portion of the n-type contact layer 101 to which the n-type electrode 85 is bonded forms a contact portion 101A attaining ohmic contact with the n-type electrode 85.

The GaN monocrystalline substrate 81 is bonded to a supporting substrate (wiring board) 90. Wires 91 and 92 are formed on the surface of the supporting substrate 90. The connecting potion 84 and the wire 91 are connected with each other by a bonding wire 93, while the n-type electrode 85 and the wire 92 are connected with each other by a bonding wire 94. Further, the light emitting diode structure and the bonding wires 93 and 94 are sealed with transparent resin such as epoxy rein (not shown), to constitute a light-emitting diode device.

The n-type contact layer 101 is formed of an n-type GaN layer to which silicon is added as an n-type dopant. The thickness of the n-type contact layer 101 is preferably set to not less than 3 μm. The doping concentration of silicon is set to 10¹⁸ cm⁻³, for example.

The aforementioned structure shown in FIG. 4 (first embodiment) or FIG. 14 (second embodiment) is applied as the multiple-quantum well layer 102. Thus, compressive stress in the quantum well layers 221 is relaxed by the barrier layers 222 (FIG. 4) or the strain compensation layer 224 (FIG. 14) made of AlGaN. Therefore, the quantum well layers 221 have excellent crystallinity with small numbers of crystal defects, whereby the light emitting diode has excellent luminous efficiency.

The p-type electron blocking layer 103 is formed of an AlGaN layer to which magnesium is added as a p-type dopant. The thickness of the p-type electron blocking layer 103 is 28 nm, for example. The doping concentration of magnesium is set to 3×10¹⁹ cm⁻³, for example.

The p-type contact layer 104 is formed of a GaN layer to which magnesium is added in a high concentration as a p-type dopant. The thickness of the p-type contact layer 104 is 70 nm, for example. The doping concentration of magnesium is set to 10²⁰ cm⁻³, for example. The surface of the p-type contact layer 104 forms a surface 82a of the group III nitride semiconductor layered portion 82, and the surface 82a is a mirror surface. The surface 82a is on a light extraction side from which light emitted in the multiple-quantum well layer 102 is extracted.

The p-type electrode 83 is formed by a transparent thin metal layer (having a thickness of not more than 20 Å, for example) constituted of an Ni layer and an Au layer. The surface 82a of the group III nitride semiconductor layered portion 82 is a mirror surface, and hence a surface 83a (surface on the light extraction side) of the p-type electrode 83 formed in contact with the surface 82a is also a mirror surface. Thus, both of the surface 82a of the group III nitride semiconductor layered portion 82 on the light extraction side and the surface 83a of the p-type electrode 83 on the light extraction side are mirror surfaces, whereby the light emitted from the multiple-quantum well layer 102 is extracted toward the p-type electrode 83 while the polarization state thereof is hardly influenced.

The n-type electrode 85 is formed by a film constituted of a Ti layer and an Al layer.

The GaN monocrystalline substrate 81 is formed of a GaN monocrystal having a major surface defined by a nonpolar plane (an m-plane in the embodiment). More specifically, the major surface of the GaN monocrystalline substrate 81 has an offset angle within ±1° from the surface orientation of the nonpolar plane.

The group III nitride semiconductor layered portion 82 of the light emitting diode 80 can be formed by the aforementioned apparatus shown in FIG. 9.

For example, a GaN monocrystalline wafer having a major surface defined by an m-plane is held by the susceptor 32 as the wafer 35. In this state, the nitrogen material valve 51 is opened while the valves 52 to 56 are kept closed, and the carrier gas and the ammonia gas (nitrogen source gas) are fed into the treating chamber 30. Further, the heater 31 is electrified, and the wafer temperature is increased up to 1000° C. to 1100° C. (1050° C., for example). Thus, GaN semiconductors can be grown without roughening the surface.

After waiting until the wafer temperature reaches 1000° C. to 1100° C., the nitrogen material valve 51, the gallium material valve 52 and the silicon material valve 56 are opened. Thus, ammonia, trimethyl gallium and silane are fed from the source gas feed passage 40 along with the carrier gas. Consequently, the n-type contact layer 101 formed of a GaN layer doped with silicon is grown on the surface of the wafer 35.

Then, the silicon material valve 56 is closed, and the multiple-quantum well layer 102 is grown. The method of forming the multiple-quantum well layer 102 is similar to that for the light emitting layer 10 according to the first or second embodiment, and hence redundant description is omitted.

Then, the p-type electron blocking layer 103 is formed. In other words, the nitrogen material valve 51, the gallium material valve 52, the aluminum material valve 53 and the magnesium material valve 55 are opened, and the remaining valves 54 and 56 are closed. Thus, ammonia, trimethyl gallium, trimethyl aluminum and ethylcyclopentadienyl magnesium are fed toward the wafer 35, to form the p-type electron blocking layer 103 consisting of an AlGaN layer doped with magnesium. In the formation of the p-type electron blocking layer 103, the temperature of the wafer 35 is preferably set to 1000° C. to 1100° C. (1000° C., for example).

Then, the p-type contact layer 104 is formed. In other words, the nitrogen material valve 51, the gallium material valve 52 and the magnesium material valve 55 are opened, and the remaining valves 53, 54 and 56 are closed. Thus, ammonia, trimethyl gallium and ethylcyclopentadienyl magnesium are fed toward the wafer 35, to form the p-type contact layer 104 consisting of a GaN layer doped with magnesium. In the formation of the p-type contact layer 104, the temperature of the wafer 35 is preferably set to 1000° C. to 1100° C. (1000° C., for example).

When the group III nitride semiconductor layered portion 82 is grown on the wafer 35 in the aforementioned manner, the wafer 35 is transferred to an etching apparatus, and a recess 87 for exposing the n-type contact layer 101 is formed by plasma etching, for example. The recess 87 may be formed to surround the multiple-quantum well layer 102, the p-type electron blocking layer 103 and the p-type contact layer 104 in an is land like manner, and the multiple-quantum well layer 102, the p-type electron blocking layer 103 and the p-type contact layer 104 may be thereby shaped into mesas.

Then, the p-type electrode 83, the connecting portion 84 and the n-type electrode 85 are formed by resistance heating or a metal vapor deposition apparatus employing an electron beam. Thus, a light emitting diode structure can be obtained.

After such a wafer process, each individual device is cut out by cleaving the wafer 35, and the individual device is connected to a leading electrode by die bonding and wire bonding, and thereafter sealed in transparent resin such as epoxy resin. Thus, the light-emitting diode device 80 is prepared.

When the layers 101 to 104 constituting the group III nitride semiconductor layered portion 82 are grown on the wafer 35 (the GaN monocrystalline substrate 81), a V/III ratio indicating the ratio of the molar fraction of the nitrogen material (ammonia) to the molar fraction of the gallium material (trimethyl gallium) fed to the wafer 35 in the treating chamber 30 is maintained at a high value of not less than 3000 in the growth of each layer. According to the embodiment, the group III nitride semiconductor layered portion 82 having the major surface defined by an m-plane or the like is grown in a dislocation-free state in a planar manner by employing the aforementioned high V/III ratio and without interposing a buffer layer between the GaN monocrystalline substrate 81 and the group III nitride semiconductor layered portion 82.

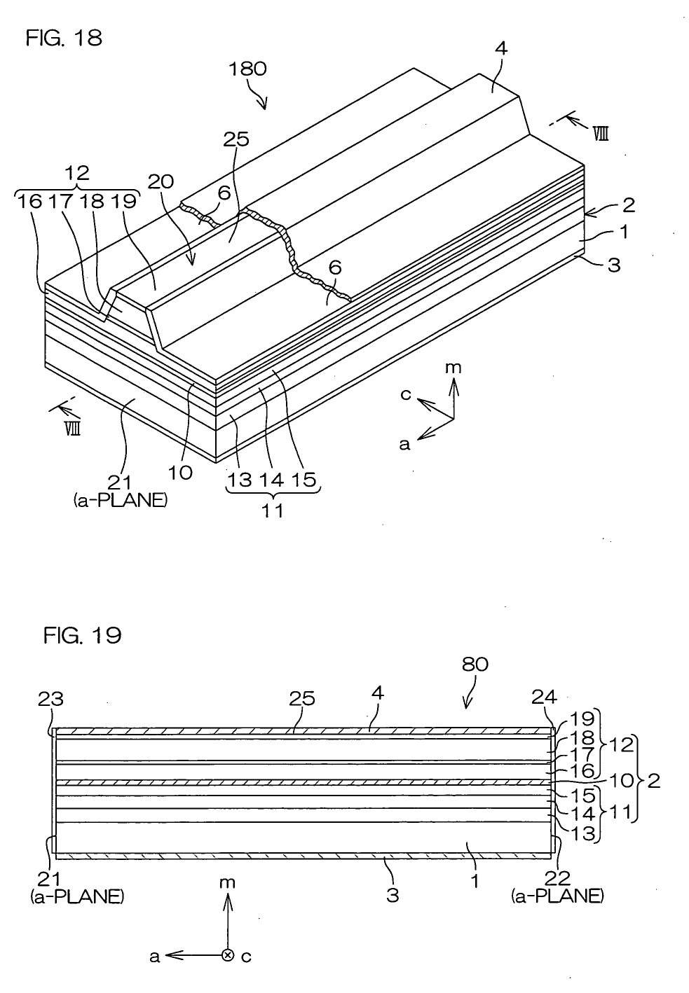

FIG. 18 is a perspective view showing the structure of a semiconductor laser diode according to a sixth embodiment of the present invention, and FIG. 19 is a longitudinal sectional view taken along a line VIII-VIII in FIG. 18. Referring to FIGS. 18 and 19, portions corresponding to those shown in FIGS. 1 to 3 are denoted by the same reference numerals.

A semiconductor laser diode 180 according to the embodiment has a major crystal growth surface defined by a nonpolar plane or a semipolar plane, and specific examples of the semipolar plane are a (10-1-1) plane, a (10-1-3) plane and the like. A ridge stripe 20 is formed parallelly to an a-axis direction, and hence both of cavity end faces 21 and 22 are defined by a-planes, while a major growth surface 25 of a p-type GaN contact layer 19 is defined by a semipolar plane.

When a group III nitride semiconductor multilayer structure 2 is epitaxially grown, stacking faults are formed parallelly to c-planes. In the structure of the aforementioned first embodiment, therefore, stacking faults and a waveguide intersect with each other. According to the present embodiment, on the other hand, a stripe direction is parallelized to an a-axis, and hence a waveguide is parallel to the a-axis. The a-axis is parallel to the c-planes, and hence no stacking faults formed parallelly to the c-plane intersect with the waveguide. Thus, hindrance of light guide and increase in a leakage current resulting from stacking faults can be avoided.

A p-type electrode 4 is formed on an insulating layer 6 and the major growth surface 25 (defined by a semipolar plane) of the p-type GaN contact layer 19, so that a lower layer of the p-type electrode 4 is in contact with the major growth surface 25 (defined by a semipolar plane) of the p-type GaN contact layer 19 exposed from the insulating layer 6. In other words, the p-type electrode 4 is so formed that a layer containing Pt is in contact with the major growth surface 25 defined by a semipolar plane. Thus, Pt (work function: 5.3 eV) can be brought into contact with the major growth surface 25 of the p-type GaN contact layer 19 defined by a semipolar plane, whereby excellent ohmic contact can be attained with respect to the p-type GaN contact layer 19. Consequently, reduction in electrical characteristics of the semiconductor laser diode 180 can be suppressed, whereby laser characteristics can be improved.

While six embodiments of the present invention have been described, the present invention may be embodied in other ways.

For example, while the ridge stripe 20 is formed parallelly to the c-axis in each of the aforementioned first to fourth embodiments, the ridge stripe 20 may be parallel to the a-axis, and the cavity end faces may be defined by a-planes. Further, the major surface of the substrate 1 is not restricted to them-plane, but may be defined by an a-plane which is another nonpolar plane, or a semipolar plane.

The thicknesses of and the impurity concentrations in the layers constituting the group III nitride semiconductor multilayer structure 2 are merely examples, and appropriate values can be properly selected and employed. Further, the cladding layers 14 and 18 may not be single layers of AlGaN, but the cladding layers can also be constituted of superlattices constituted of AlGaN layers and GaN layers.

The substrate 1 may be removed by laser lift off or the like after the group III nitride semiconductor multilayer structure 2 is formed, so that the semiconductor laser diode has no substrate 1. In this case, the n-type electrode 3 is formed to be in contact with the rear surface of the n-type GaN contact layer 13 exposed due to the removal of the substrate 1. More specifically, the group III nitride semiconductor multilayer structure 2 is bonded to a supporting substrate with an adhesive such as wax, for example, and supported after the formation of the p-type electrode 4. Then, the substrate 1 is removed by chemical mechanical polishing or etching, for example, and the rear surface of the n-type GaN contact layer 13 is exposed. The n-type electrode 3 is formed on the exposed rear surface of the n-type GaN contact layer 13. The supporting substrate having supported the group III nitride semiconductor multilayer structure 2 is removed by dissolving the wax at a temperature of not more than 400° C., for example, and preferably not more than 200° C. Also in this case, the process temperature for dissolving the wax after the formation of the p-type electrode 4 is maintained at not more than 400° C., for example, and preferably not more than 200° C. In other words, the temperature to which the p-type electrode 4 is exposed is maintained at not more than 400° C. Therefore, reduction in the ohmic property of the p-type electrode 4 excellently in ohmic contact with the p-type GaN contact layer 19 can be suppressed. Consequently, reduction in the electrical characteristics can be suppressed in the semiconductor laser diode 70.

While the strain compensation layer is provided in the multiple-quantum well layer 102 in the aforementioned fifth embodiment, the structure shown in FIG. 15 or 16 may alternatively be employed. In other words, an n-type AlGaN strain compensation layer may be provided in the n-type contact layer 101 adjacent to the multiple-quantum well layer 102. The n-type AlGaN strain compensation layer, preferably provided to be in contact with the multiple-quantum well layer 102 according to the structure shown in FIG. 15, may be provided in a layer-thickness intermediate portion of the n-type contact layer 101 according to the structure shown in FIG. 16.

While the light emitting diode has the group III nitride semiconductor multilayer structure having the major growth surface defined by an m-plane which is a nonpolar plane in the aforementioned fifth embodiment, the diode structure may alternatively be formed by a group III nitride semiconductor multilayer structure having a major growth surface defined by an a-plane which is another nonpolar plane. Further, the present invention is not restricted to the nonpolar plane, but is applicable also when the diode structure is formed by a group III nitride semiconductor multilayer structure having a major growth surface defined by a semipolar plane.

While the light emitting layer has the light emitting layer of the multiple-quantum well structure provided with a plurality of quantum well layers in each of the aforementioned embodiments, the light emitting layer may alternatively have a quantum well structure provided with a single quantum well layer.

### EXAMPLES

While the present invention is now described with reference to Examples, the present invention is not restricted to the following Examples.

### Examples 1 to 3

In each of Examples 1 to 3, a semiconductor laser diode having the structure shown in FIGS. 1 to 3 was prepared according to the manufacturing steps described with reference to the first embodiment.

In Example 1, a p-type electrode made of Pt/Au metal was not annealed after formation thereof. In Examples 2 and 3, p-type electrodes were annealed at temperatures of 200° C. and 400° C. respectively.

### Examples 4 to 7

In each of Examples 4 to 7, a semiconductor laser diode having the structure shown in FIGS. 1 to 3 was prepared according to the manufacturing steps described with reference to the first embodiment, except that an electrode made of Pd/Au metal having a two-layer structure consisting of a lower layer containing Pd and an upper layer containing Au was formed as a p-type electrode.

In Example 4, the p-type electrode made of Pd/Au metal was not annealed after formation thereof. In Examples 5 to 7, the p-type electrodes were annealed at temperatures of 200° C., 400° C. and 600° C. respectively.

### (Evaluation Test)

1) Electrification Test

An electrification test was conducted by injecting a direct current to the semiconductor laser diode prepared in each Example at room temperature while varying the direct current from 0 mA to 100 mA.

2) Evaluation of Forward Voltage (Vf)

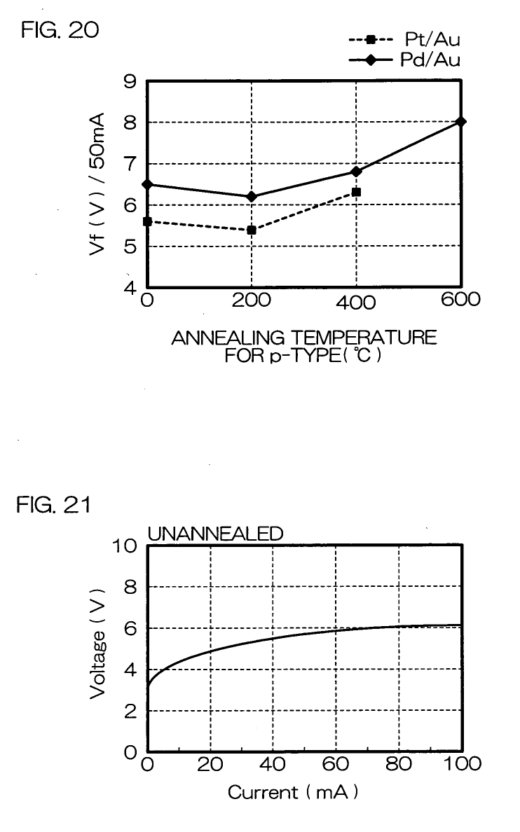

In the electrification test 1), forward voltages (Vf) of the semiconductor laser diodes prepared according to Examples were compared and evaluated with an injection current of 50 mA. FIG. 20 shows the results.

As shown in FIG. 20, the forward voltages Vf of the semiconductor laser diodes according to Example 1 (annealing temperature: 0° C.), Example 2 (annealing temperature: 200° C.) and Example 3 (annealing temperature: 400° C.) having the p-type electrodes made of Pt/Au metal were 5.6 V, 5.4 V and 6.3 V respectively.

On the other hand, the forward voltages Vf of the semiconductor laser diodes according to Example 4 (annealing temperature: 0° C.), Example 5 (annealing temperature: 200° C.), Example 6 (annealing temperature: 400° C.) and Example 7 (annealing temperature: 600° C.) having the p-type electrodes made of Pd/Au metal were 6.5 V, 6.2 V, 6.8 V and 8.0 V respectively.

Thus, it has been confirmed that resistance between the p-type electrode and a p-type GaN contact layer is lower and the p-type electrode is excellently in ohmic contact with the p-type GaN contact layer in the semiconductor laser diode having the p-type electrode made of Pt/Au metal as compared with the semiconductor laser diode having the p-type electrode made of Pd/Au metal.

3) Evaluation of Current-Voltage Characteristics (I-V Characteristics)

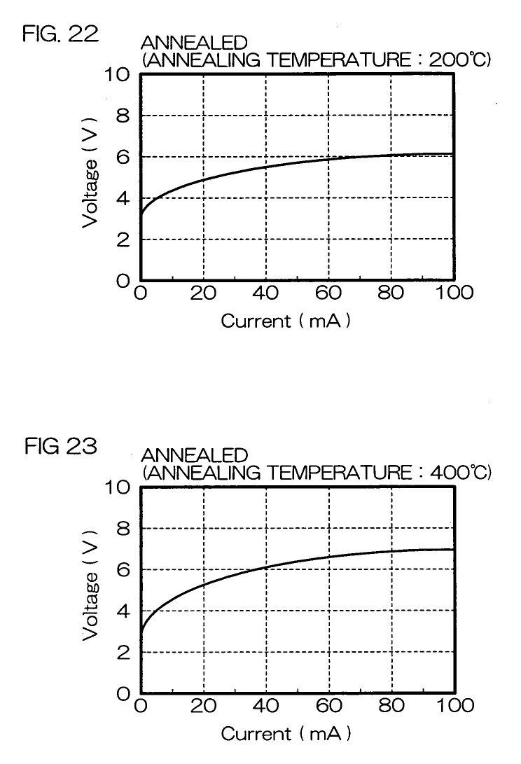

Changes in the forward voltages (Vf) of the semiconductor laser diodes prepared according to Examples 1 to 3 were evaluated while varying the injection current from 0 mA to 100 mA in the electrification test 1). FIGS. 21 to 23 show the I-V curves.

As shown in FIGS. 21 to 23, the forward voltages Vf of the semiconductor laser diodes according to Examples 1 to 3 with the injection current of 50 mA were 5.6 V, 5.4 V and 6.3 V respectively, for example.

Thus, it has been confirmed that the resistance between the p-type electrode and the p-type GaN contact layer was low and the p-type electrode was excellently in ohmic contact with the p-type GaN contact layer in each of the semiconductor laser diodes according to Examples 1 to 3. In particular, it has been confirmed that the p-type electrode was excellently in ohmic contact with the p-type GaN contact layer in each of the semiconductor laser diode according to Example 1 having the p-type electrode not annealed after the formation thereof and the semiconductor laser diode according to Example 2 having the p-type electrode annealed at the temperature of 200° C. after the formation thereof.

When a major growth surface is different, an atomic composition on the surface of GaN is different. In GaN having a major surface defined by a c-plane, for example, the atomic composition on the surface is generally entirely formed by Ga atoms. In GaN having a major surface defined by an m-plane, on the other hand, the atomic composition on the surface is formed by Ga atoms and N atoms in the ratio of 1:1.

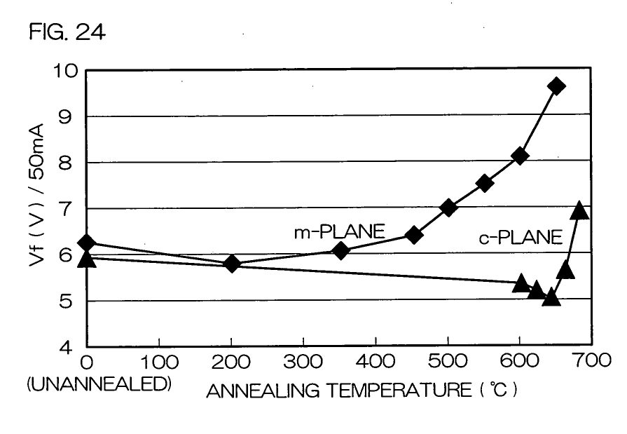

Therefore, GaN and metal are different in reactivity in annealing. For example, proper values of a temperature (annealing temperature) for annealing are different. When a Pd/Au electrode is applied as a p-type electrode of GaN having a major surface defined by a c-plane, a proper annealing temperature is 640° C., as shown in FIG. 24. If the annealing temperature is 640° C., excellent ohmic contact can be attained due to alloying reaction between Pd and GaN. When a Pd/Au electrode is applied as a p-type electrode of GaN having a major surface defined by an m-plane, on the other hand, a proper annealing temperature is 200° C. In other words, the proper annealing temperature is low as compared with the case where the major growth surface of GaN is defined by a c-plane, no alloying reaction is caused between Pd and GaN at the temperature, and it is difficult to attain excellent ohmic contact.

While the present invention has been described in detail byway of the embodiments thereof, it should be understood that these embodiments are merely illustrative of the technical principles of the present invention but not limitative of the invention. The spirit and scope of the present invention are to be limited only by the appended claims.

In addition to the features recited in claims, other features to be grasped by the disclosure of the present invention are as follows:

(A1) A semiconductor laser device made of a group III nitride semiconductor having a major growth surface defined by a nonpolar plane or a semipolar plane: including an active layer of a quantum well structure having a quantum well layer containing In, and a barrier layer containing Al and having a thickness of 3 nm to 8 nm.

The quantum well layer is made of a group III nitride semiconductor containing In (an InGaN layer, for example), and hence has a relatively large lattice constant in a strain-free state. When the quantum well layer is coherently grown on an underlayer (a GaN layer, for example), therefore, compressive strain is caused in a direction along the major growth surface (defined by a nonpolar plane or a semipolar plane). On the other hand, the barrier layer is made of a group III nitride semiconductor containing Al, and hence has a relatively small lattice constant in a strain-free state. When the barrier layer is coherently grown on an underlayer, therefore, tensile strain is caused in the direction along the major growth surface (defined by a nonpolar plane or a semipolar plane). Therefore, the barrier layer containing Al functions as a strain compensation layer in a manner of speaking, and relaxes compressive stress in the quantum well layer. Consequently, the number of crystal defects in the quantum well layer can be reduced, whereby luminous efficiency can be improved.

On the other hand, the refractive index of the group III nitride semiconductor containing Al is lower than that of InGaN or the like, and hence an average refractive index around the active layer required to most strongly confine light is reduced if the group III nitride semiconductor containing Al is employed for the barrier layer.

Therefore, the thickness of the barrier layer containing Al is set to not less than 3 nm and not more than 8 nm. If the thickness of the barrier layer is less than 3 nm, the function of the barrier layer is insufficient. If the thickness of the barrier layer exceeds 8 nm, on the other hand, light confinement is weakened, and a threshold current is increased. The thickness of the barrier layer is more preferably in the range of 5 nm to 7 nm.

The quantum well layer may be formed by an InGaN layer. An emission wavelength thereof can be adjusted by adjusting the In composition.

The barrier layer may be formed by an AlGaN layer, for example. A small quantity of In may be incorporated into the AlGaN layer.

(A2) The semiconductor laser device according to Item A1, wherein the A1 composition in the barrier layer is not more than 5%.

The refractive index of the barrier layer is reduced and the average refractive index around the active layer is reduced as the Al composition is increased. Therefore, light can be strongly confined around the active layer by setting the Al composition in the barrier layer to not more than 5%.

(A3) The semiconductor laser device according to Item A1 or A2, further including a guide layer made of a group III nitride semiconductor containing In stacked on the active layer.

According to such a structure, compressive stress is caused also in the guide layer, and hence the number of crystal defects resulting from compressive stress in the quantum well layer may be increased. When the emission wavelength of the active layer is set in a long-wave range of not less than 450 nm, for example, an InGaN layer is preferably applied to the guide layer. According to the structure, the number of crystal defects in the quantum well layer can be effectively reduced by providing the barrier layer containing Al in the active layer.

(A4) The semiconductor laser device according to any one of Items A1 to A3, further including a cladding layer made of a group III nitride semiconductor having an average Al composition of not more than 5% stacked on the active layer.

When the emission wavelength of the active layer is set in the long-wave range of not less than 450 nm, for example, an AlGaN layer may be applied to the cladding layer. An excellent light confining structure can be formed by setting the average Al composition in the cladding layer to not more than 5%.

(A5) The semiconductor laser device according to any one of Items A1 to A4, wherein the thickness of the quantum well layer is not more than 100 Å.

When the thickness of the quantum well layer is set to not more than 100 Å, luminous efficiency can be improved due to a quantum effect. The number of crystal defects resulting from compressive stress in such a thin quantum well layer is reduced due to the barrier layer having the function of a strain compensation layer. Therefore, excellent luminous efficiency and a low threshold current can be implemented synergistically with the quantum effect.

(A6) The semiconductor laser device according to any one of Items A1 to A5, wherein the major growth surface is defined by an m-plane.

A group III nitride semiconductor crystal having a major surface defined by an m-plane is stably grown, and has excellent crystallinity. Compressive stress in the quantum well layer can be effectively reduced by applying the barrier layer having the function as the strain compensation layer to the semiconductor laser device constituted of such a group III nitride semiconductor having excellent crystallinity, and hence the quantum well layer has an extremely small number of crystal defects. Thus, excellent luminous efficiency and a low threshold current can be implemented.

(B1) A nitride semiconductor device: having a p-type group III nitride semiconductor layer having a major surface defined by a nonpolar plane or a semipolar plane, and an electrode formed on the major surface of the p-type group III nitride semiconductor layer and containing Pt in a contact region in contact with the major surface.

According to the structure, the major surface of the p-type group III nitride semiconductor layer is defined by a nonpolar plane or a semipolar plane. In the electrode formed on the major surface having the aforementioned surface orientation, Pt is contained in the contact region in contact with the major surface. Thus, Pt can be brought into contact with the major surface defined by a nonpolar plane or a semipolar plane, whereby excellent ohmic contact can be attained with respect to the p-type group III nitride semiconductor layer. Consequently, reduction in electrical characteristics of the nitride semiconductor device can be suppressed. The nonpolar plane is an a-plane or an m-plane. Specific examples of the semipolar planes are a (10-1-1) plane, a (10-1-3) plane, a (11-22) plane and the like.

(B2) The nitride semiconductor device according to Item B1, wherein the major surface of the p-type group III nitride semiconductor layer is defined by an m-plane.

When the major surface of the p-type group III nitride semiconductor layer is defined by an m-plane, crystal growth can be extremely stably performed, and crystallinity can be improved as compared with a case of defining the major surface of crystal growth by a c-plane or another crystal plane. Consequently, a high-performance nitride semiconductor device can be prepared.

(C1) A method of manufacturing a nitride semiconductor device having an electrode on a major surface of a p-type group III nitride semiconductor layer having the major surface defined by a nonpolar plane or a semipolar plane: including an electrode forming step of forming an electrode material containing Pt to be in contact with the major surface.

According to the method, the electrode is formed so that the electrode material containing Pt is in contact with the major surface (defined by a nonpolar plane or a semipolar plane) of the p-type group III nitride semiconductor layer, whereby Pt can be brought into contact with the major surface defined by a nonpolar plane or a semipolar plane. Therefore, excellent ohmic contact can be attained with respect to the p-type group III nitride semiconductor layer. Consequently, reduction in electrical characteristics can be suppressed in the nitride semiconductor device.

(C2) The method according to Item C1, further including an annealing step of annealing the electrode material at a temperature of not more than 400° C. after the electrode forming step.

A group III nitride semiconductor having a major surface defined by a c-plane and a group III nitride semiconductor having a major surface defined by a nonpolar plane or a semipolar plane have different atomic compositions on the surfaces. Therefore, the group III nitride semiconductors and the electrode material are different in reactivity from one another in the annealing. For example, proper values of the temperature (annealing temperature) for the annealing are different. When the electrode material containing Pt is formed on a p-type GaN layer having a major growth surface defined by an m-plane and the material is annealed, a proper annealing temperature is 200° C., and a contact property of the electrode with respect to the p-type GaN layer may be reduced if the annealing temperature exceeds 400° C.

When annealing the electrode formed on the major surface (defined by a nonpolar plane or a semipolar plane) of the p-type group III nitride semiconductor layer, therefore, the annealing temperature is preferably not more than 400° C. If the electrode material is annealed at a temperature of not more than 400° C., reduction in the ohmic property of the electrode with respect to the p-type group III nitride semiconductor layer can be suppressed. Consequently, reduction in the electrical characteristics of the nitride semiconductor device can be suppressed.

(C3) The method according to Item C2, wherein the annealing step is a step of annealing the electrode material at a temperature of 200° C.

As hereinabove described, the proper value of the annealing temperature for the electrode formed on the m-plane which is an example of the nonpolar plane is 200° C. When the electrode material is annealed at 200° C., therefore, the electrode can be extremely excellently brought into ohmic contact with the p-type group III nitride semiconductor layer. Consequently, excellent electrical characteristics can be attained in the nitride semiconductor device.

(C4) The method according to Item C1, wherein no annealing is performed after the electrode forming step.

Pt (work function: 5.3 eV) has a work function larger than that of Pd (work function: 5.1 eV). Therefore, excellent ohmic contact can be attained also when no alloying reaction is caused between the p-type group III nitride semiconductor and the electrode material containing Pt. Also when no annealing is performed after the electrode forming step, therefore, excellent ohmic contact can be attained, and excellent electrical characteristics can be attained in the nitride semiconductor device.

(C5) The method according to any one of Items C1 to C4, wherein a process temperature to which the electrode material is exposed is maintained at not more than 400° C. in a step following the electrode forming step.

When the electrode material formed on the major surface (defined by a nonpolar plane or a semipolar plane) of the p-type group III nitride semiconductor layer is annealed at a temperature exceeding 400° C., the ohmic property of the electrode with respect to the p-type group III nitride semiconductor layer may be reduced to reduce the electrical characteristics of the nitride semiconductor device, as hereinabove described. Therefore, reduction in the ohmic property of the electrode with respect to the p-type group III nitride semiconductor layer can be suppressed by maintaining the process temperature to which the electrode is exposed at not more than 400° C. in the step following the electrode forming step. Consequently, reduction in the electrical characteristics of the nitride semiconductor device can be suppressed.

(C6) The method according to any one of Items C1 to C5, wherein a process temperature to which the electrode material is exposed is maintained at not more than 200° C. in a step following the electrode forming step.

As hereinabove described, excellent electrical characteristics can be attained in the nitride semiconductor device by annealing the electrode material at the temperature of 200° C. or performing no annealing. Therefore, the process temperature to which the electrode material is exposed is maintained at not more than 200° C. in the step following the electrode forming step. Thus, the electrode can be extremely excellently brought into ohmic contact with the p-type group III nitride semiconductor layer. Consequently, excellent electrical characteristics can be attained in the nitride semiconductor device.

This application corresponds to Japanese Patent Application No. 2008-54705 filedwiththe Japanese Patent Office on Mar. 5, 2008, Japanese Patent Application No. 2008-84219 filed with the Japanese Patent Office on Mar. 27, 2008 and Japanese Patent Application No. 2008-84220 filed with the Japanese Patent Office on Mar. 27, 2008, the entire disclosures of which are incorporated herein by reference.

What is claimed is:

1. A semiconductor light emitting device made of a group III nitride semiconductor having a major growth surface defined by a nonpolar plane or a semipolar plane, the semiconductor light emitting device having a quantum well layer containing In in a light emitting layer, wherein
a strain compensation layer made of a group III nitride semiconductor containing Al and having a lattice constant smaller than a lattice constant of the quantum well layer in a strain-free state is interposed in the light emitting layer of a quantum well structure having the quantum well layer and a barrier layer or in an adjacent layer adjacent to the light emitting layer.

2. The semiconductor light emitting device according to claim 1, wherein
the strain compensation layer is provided in the barrier layer.

3. The semiconductor light emitting device according to claim 2, wherein
the strain compensation layer is provided to be in contact with the quantum well layer.

4. The semiconductor light emitting device according to claim 1, wherein
the strain compensation layer is provided in the adjacent layer and in contact with the quantum well structure.

5. The semiconductor light emitting device according to claim 4, wherein
the strain compensation layer is in contact with the barrier layer of the quantum well structure.

6. The semiconductor light emitting device according to claim 1, wherein
the strain compensation layer is provided in the adjacent layer and not in contact with the quantum well structure.

7. The semiconductor light emitting device according to claim 1, wherein
the adjacent layer is made of a group III nitride semiconductor containing In.

8. The semiconductor light emitting device according to claim 1, wherein
the adjacent layer includes a guide layer and a cladding layer, and the cladding layer is made of a group III nitride semiconductor having an average Al composition of not more than 5%.

9. The semiconductor light emitting device according to claim 1, wherein
the barrier layer contains Al, and has a thickness of 3 nm to 8 nm.

10. The semiconductor light emitting device according to claim 9, wherein
the Al composition in the barrier layer is not more than 5%.

11. The semiconductor light emitting device according to claim 1, further comprising a guide layer made of a group III nitride semiconductor containing In stacked on the light emitting layer.

12. The semiconductor light emitting device according to claim 1, further comprising a cladding layer made of a group III nitride semiconductor having an average Al composition of not more than 5% stacked on the light emitting layer.

13. The semiconductor light emitting device according to claim 1, wherein
the quantum well structure includes at least one quantum well layer having a thickness of not more than 100 Å.

14. The semiconductor light emitting device according to claim 1, wherein
the major growth surface is defined by an m-plane.

15. The semiconductor light emitting device according to claim 1, wherein
the group III nitride semiconductor having the major growth surface defined by a nonpolar plane or a semipolar plane includes a p-type group III nitride semiconductor layer, and
the semiconductor light emitting device further comprises an electrode formed on a major surface of the p-type group III semiconductor layer, the electrode containing Pt in a contact region in contact with the major surface.
